(19) United States
(12) Patent Application Publication
(10) Pub. No.: US 2026/0156845 A1
(43) Pub. Date: Jun. 4, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ming-Hung WU, Kaohsiung City (TW); Min-Ying TSAI, Kaohsiung City (TW); Sheng-Chau CHEN, Tainan City (TW)

(21) Appl. No.: 18/965,111

(22) Filed: Dec. 2, 2024

(51) Int. Cl. H10D 1/68; H10D 1/00

(52) U.S. Cl. CPC H10D 1/716; H10D 1/042

(57) ABSTRACT

A semiconductor device includes a capacitor structure that includes an insulator layer stack with a plurality of aluminum oxide layers and a plurality of zirconium oxide layers. The insulator layer stack is formed on a bottom electrode layer of the capacitor structure. The arrangement of the aluminum oxide layers at a bottom and a top of the insulator layer stack prevents oxygen migration from the zirconium oxide layers to the electrode layers of the capacitor structure, while achieving higher capacitance levels than those of capacitor structures with differently arranged insulator layers. In addition, since the aluminum oxide layers of the insulator layer stack prevent oxygen migration from the zirconium oxide layers of the insulator layer stack to the electrode layers of the capacitor structure, faster discharge times can be achieved for the capacitor structure.

### BACKGROUND

A capacitor structure, such as a deep trench capacitor (DTC) structure, may include a metal-insulator-metal (MIM) structure in which an insulator layer is sandwiched between two conductive electrode layers. Various types of semiconductor devices may include one or more capacitor structures, such as an image sensor device, a memory device (e.g., a dynamic random access memory (DRAM) device), a logic device, a processor, a system on chip (SoC), and/or an integrated passive device (IPD), among other examples.

In a semiconductor device, a capacitor structure may be included in an interconnect layer (e.g., an interconnect region) of the semiconductor device. The capacitor structure may extend through a plurality of dielectric layers in the interconnect layer and may be electrically coupled to one or more conductive structures in the interconnect layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of example circuits for a pixel sensor described herein.

FIGS. 2A-2C are diagrams of an example semiconductor device described herein.

FIGS. 3A-3E are diagrams of an example implementation of forming a semiconductor device described herein.

FIGS. 4A-4Q are diagrams of an example implementation of forming a trench capacitor structure described herein.

FIGS. 5A-5C are diagrams of example implementations of an insulator layer of a capacitor structure described herein.

FIG. 6 illustrates an elemental composition of a portion of a capacitor structure described herein.

FIG. 7 is a diagram of an example implementation of a portion of a capacitor structure described herein.

FIG. 8 is a diagram of an example semiconductor device described herein.

FIG. 9 is a diagram of an example semiconductor device described herein.

FIG. 10 is a diagram of an example semiconductor device described herein.

FIG. 11 is a flowchart of an example process associated with forming a semiconductor device described herein.

FIG. 12 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, some insulating layers of a high-density metal-insulator-metal (MIM) capacitor may degrade, resulting in decreased performance for the MIM capacitor. For example, an insulator layer stack of zirconium oxide (ZrOₓ such as ZrO₂) and aluminum oxide (AlₓO_{y} such as Al₂O₃), such as a ZrO₂/Al₂O₃/ZrO₂ (ZAZ) dielectric layer stack, may be susceptible to charge trapping, which can lead to delays in discharging an MIM capacitor that includes the insulator layer stack. With a ZrO₂/Al₂O₃/ZrO₂ (ZAZ) arrangement, oxygen may diffuse from the zirconium oxide in the zirconium oxide layers to adjacent electrode layers of the MIM capacitor, leading to crystal defects referred to as oxygen vacancies. These oxygen vacancies may act as electron traps that trap electrons in the MIM capacitor (e.g., from the electrode layers of the MIM capacitor), which increases the discharge time for the MIM capacitor.

The increased discharge time for the MIM capacitor may lead to lag in generating images and/or video in use cases in which the MIM capacitor is included in an image sensor device for charge overflow storage. Additionally and/or alternatively, the increased discharge time for the MIM capacitor may lead to longer read times and/or longer erase times for a memory cell (e.g., a DRAM cell) in which the MIM capacitor is included in a memory device. Additionally and/or alternatively, the increased discharge time for the MIM capacitor may lead to reduce charge smoothing performance where the MIM capacitor is included in a power supply. In an effort to reduce or prevent the migration of oxygen from the zirconium oxide layers of a ZrO₂/Al₂O₃/ZrO₂ (ZAZ) arrangement, a nitrous oxide (N₂O) surface treatment of the bottom electrode layer may be performed, which creates an interlayer that acts as an oxygen diffusion barrier layer between the bottom electrode layer and the lower zirconium oxide layer of a ZrO₂/Al₂O₃/ZrO₂ (ZAZ) arrangement. The interlayer may be an oxide and/or oxynitride of the metal of the bottom electrode layer. For example, the interlayer may include titanium oxide (e.g., TiOₓ such as TiO₂) and/or titanium oxynitride (TiOₓN_{y}). While the interlayer may reduce or prevent oxygen migration from zirconium oxide of a ZrO₂/Al₂O₃/ZrO₂ (ZAZ) arrangement to the electrode layers of the MIM capacitor, the addition of the interlayer reduces a total capacitance of the MIM capacitor.

In some implementations described herein, a semiconductor device (e.g., a complementary metal-oxide-semiconductor (CMOS) image sensor device, a memory device, a logic device) includes a capacitor structure (e.g., an MIM capacitor) that includes a dielectric layer stack in which the outer (e.g., upper and lower) layers are aluminum oxide (Al₂O₃) instead of another dielectric material such as zirconium oxide (ZrO₂). For example, the dielectric layer stack may include an Al₂O₃/ZrO₂/Al₂O₃/ZrO₂/Al₂O₃(AZAZA) dielectric layer stack (or another quantity of alternating Al₂O₃/ZrO₂ layers where the outer layers are Al₂O₃) that is formed on the bottom electrode layer of the MIM capacitor without an intervening interlayer between the upper and lower aluminum oxide layers of the dielectric layer stack and the electrode layers of the MIM capacitor.

The arrangement of the aluminum oxide layers at a bottom and at a top of the dielectric layer stack prevents oxygen migration from the zirconium oxide layers to the electrode layers of the MIM capacitor, while achieving higher capacitance levels than those of MIM capacitors incorporating other types of dielectric materials in the outer layers in a dielectric stack of an insulator layer, such as a ZrO₂/Al₂O₃/ZrO₂ (ZAZ) dielectric layer stack and an interlayer. In particular, the outer aluminum oxide layers of the dielectric layer stack are more resistant to oxygen migration than the zirconium oxide layers of the dielectric layer stack, and therefore exhibit less oxygen loss to the electrode layers of the MIM capacitor (and, accordingly, fewer oxygen vacancies). The fewer oxygen vacancies in the outer aluminum oxide layers results in the outer aluminum oxide layers being less susceptible to charge trapping, thereby enabling faster discharge times to be achieved for the MIM capacitor. The faster discharge times for the MIM capacitor may enable images and/or video to be generated with reduced lag in use cases in which the MIM capacitor is included in image sensor device for charge overflow storage. Additionally and/or alternatively, the faster discharge times for the MIM capacitor may enable faster read times and/or faster erase times to be achieved for a memory cell (e.g., a DRAM cell) in which the MIM capacitor is included in a memory device. Additionally and/or alternatively, the faster discharge times for the MIM capacitor may enable increased charge smoothing performance where the MIM capacitor is included in a power supply.

Omitting the interlayer enables the MIM capacitor to exhibit higher total capacitance in that the dielectric layer stack of the insulator layer of the MIM capacitor includes high dielectric constant materials such as aluminum oxide and zirconium oxide without lower dielectric constant materials that are used for the interlayer. In addition, omitting the interlayer reduces process complexity for manufacturing the MIM capacitor in that the nitrous oxide (N₂O) surface treatment of the bottom electrode layer is omitted, thereby reducing the quantity of process steps for manufacturing the MIM capacitor.

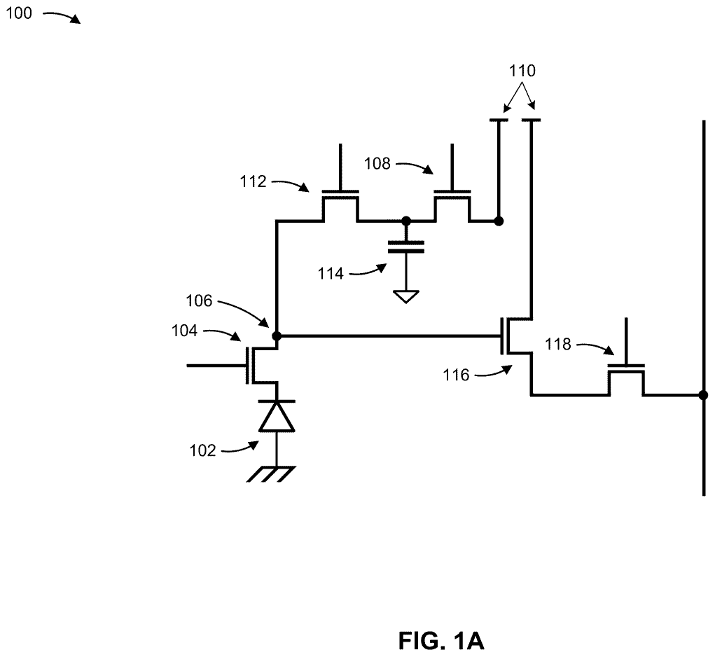

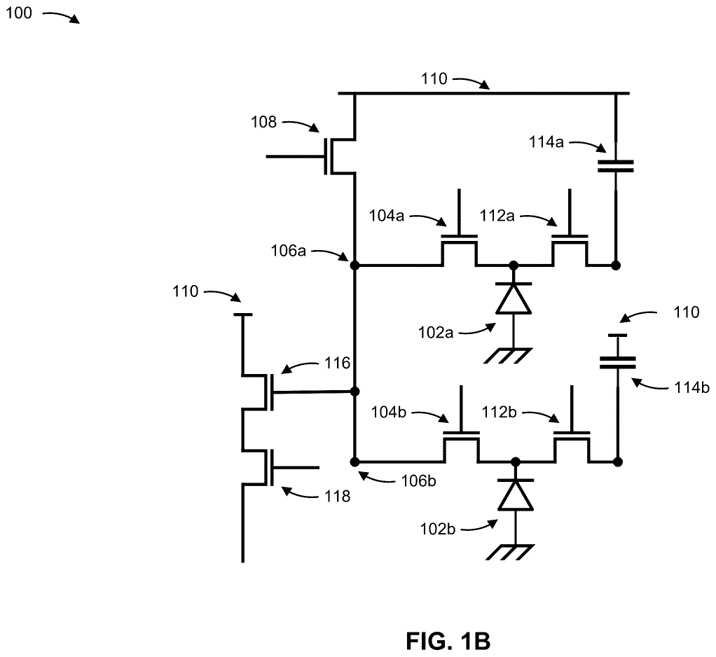

FIGS. 1A and 1B are diagrams of example circuits for a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

As shown in an example circuit in FIG. 1A, a pixel sensor 100 includes a photodiode 102 that may be configured to sense and/or accumulate incident light (e.g., light directed toward the pixel sensor 100) and convert photons of the incident light to a photocurrent. The magnitude of the photocurrent may be based on the number of photons (e.g., the intensity of the incident light) collected in the photodiode 102. Thus, the accumulation of photons in the photodiode 102 generates a build-up of electrical charge that represents the intensity or brightness of the incident light (e.g., a greater amount of charge may correspond to a greater intensity or brightness, and a lesser amount of charge may correspond to a lower intensity or brightness).

The photodiode 102 is electrically connected to a transfer gate 104. The transfer gate 104 is configured to control the transfer of the photocurrent from the photodiode to a floating diffusion node 106. The transfer gate 104 may be selectively switched by applying a transfer voltage (Vₜₓ) to the transfer gate 104. In some implementations, the transfer voltage being applied to the transfer gate 104 causes a leakage path (e.g., a buried channel) to form between the photodiode 102 and the floating diffusion node 106 across the transfer gate 104, which enables the photocurrent to travel along the leakage path to the floating diffusion node 106. In some implementations, the transfer voltage being removed from the transfer gate 104 (or the absence of the transfer voltage) causes the leakage path to be removed, such that the photocurrent cannot pass from the photodiode 102 to the floating diffusion node 106.

The circuit for the pixel sensor 100 may further include a reset gate 108. The reset gate 108 is electrically connected to a voltage source 110. The reset gate 108 may be controlled to selectively apply a reset voltage (Vᵣₛₜ) to the floating diffusion node 106 from the voltage source 110. The transfer gate 104 and the reset gate 108 may be electrically coupled to the floating diffusion node 106 such that the reset voltage is applied to the floating diffusion node 106 to “reset” the floating diffusion node 106 (e.g., by draining any residual charge in the floating diffusion node 106) prior to activation of the transfer gate 104 to transfer a photocurrent from the photodiode 102 to the floating diffusion node 106.

The pixel sensor 100 may be a lateral overflow integration capacitor (LOFIC) pixel sensor that includes an overflow gate 112 and an overflow capacitor 114. The overflow capacitor 114 may be electrically coupled to the floating diffusion node 106 through the overflow gate 112 such that photocurrent may be transferred from the floating diffusion node 106 to the overflow capacitor 114 for temporary storage. The overflow gate 112 may selectively control the flow of photocurrent to and/or from the overflow capacitor 114. This enables additional photocurrent to be transferred to the floating diffusion node 106 from the photodiode 102 without causing the pixel sensor 100 to reach saturation, which increases the full well capacity and the dynamic range of the pixel sensor 100.

The photocurrent may be used to apply a floating diffusion voltage (V_{fd}) to a source follower gate 116 of the circuit of the pixel sensor 100. This permits the photocurrent to be observed without removing or discharging the photocurrent from the floating diffusion node 106 and/or from the overflow capacitor 114. The reset gate 108 may instead be used to remove or discharge the photocurrent from the floating diffusion node 106 and/or from the overflow capacitor 114.

To apply the floating diffusion voltage to the source follower gate 116, the transfer gate 104 may be switched off (e.g., so that the photocurrent does not flow back into the photodiode 102) and the overflow gate 112 may be switched on. This configuration enables the photocurrent stored in floating diffusion node 106 and in the overflow capacitor 114 to be used to apply the floating diffusion voltage to the source follower gate 116.

The source follower gate 116 functions as a high impedance amplifier for the pixel sensor 100. The source follower gate 116 provides a voltage-to-current conversion of the floating diffusion voltage. The output of the source follower gate 116 is electrically connected to a row select gate 118, which is configured to control the flow of the photocurrent to external circuitry. The row select gate 118 is controlled by selectively applying a select voltage (V_{di}) to the gate of the row select gate 118. This permits the photocurrent to flow to an output of the pixel sensor 100.

As shown in another example circuit in FIG. 1B, a pixel sensor 100 may include a plurality of subcircuits. The subcircuits may include a small pixel subcircuit and a large pixel subcircuit. The small pixel subcircuit may include a small photodiode 102a, a transfer gate 104a, a floating diffusion node 106a, an overflow gate 112a, and an overflow capacitor 114a. The large pixel sensor subcircuit may include a large photodiode 102b, a transfer gate 104b, a floating diffusion node 106b, an overflow gate 112b, and an overflow capacitor 114b. The small pixel subcircuit and the large pixel subcircuit may both be connected to the reset gate 108, the voltage source 110, the source follower gate 116, and the row select gate 118. The large photodiode 102b may be physically larger than the small photodiode 102a, thereby enabling pixel sensor 100 to have different regions of photonic sensitivity.

As indicated above, FIGS. 1A and 1B are provided as examples. Other examples may differ from what is described with regard to FIGS. 1A and 1B.

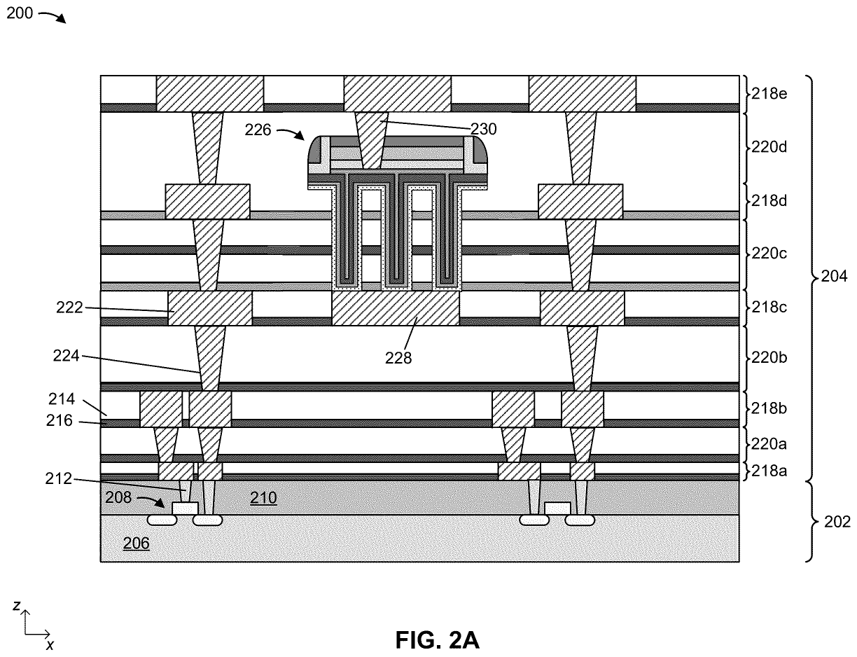

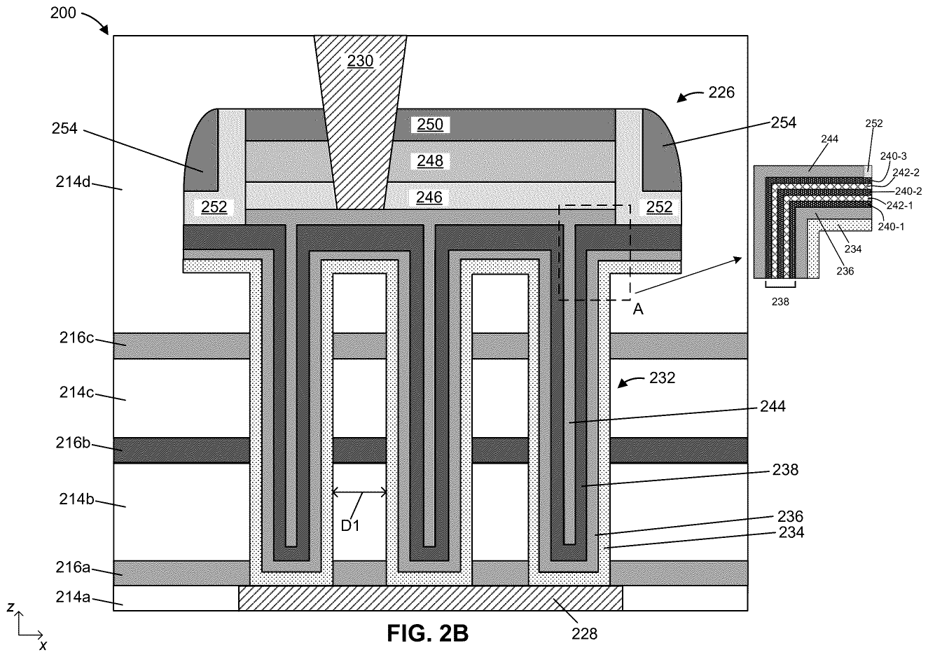

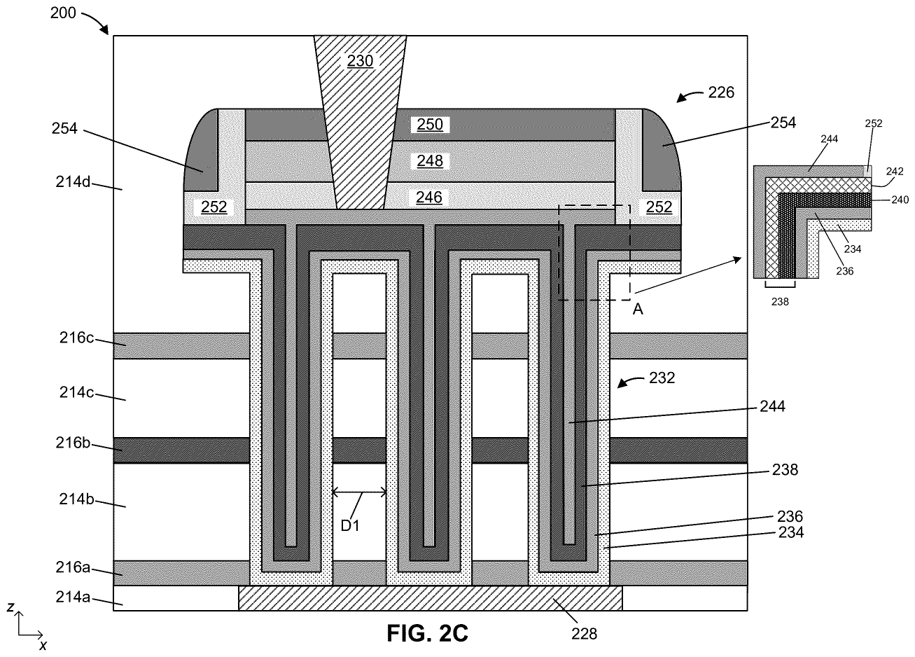

FIGS. 2A-2C are diagrams of an example semiconductor device 200 described herein. The semiconductor device 200 may include a system-on-chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device. In the case of an image sensor device, the semiconductor device 200 may include an example structural implementation of an overflow capacitor 114 of a pixel sensor 100 described herein.

FIG. 2A illustrates a cross-section view of the semiconductor device 200. As shown in FIG. 2A, the semiconductor device 200 may include a device layer 202 and an interconnect layer 204 arranged in a z-direction in the semiconductor device 200 with respect to the device layer 202. For example, the interconnect layer 204 may be located above the device layer 202. As another example, the interconnect layer 204 may be located below the device layer 202.

The interconnect layer 204 may include conductive structures that are arranged to carry signals and/or provide power distribution throughout the semiconductor device 200. In some implementations, the semiconductor device 200 includes interconnect layers 204 above and below the device layer 202. A first interconnect layer 204 on a first side of the device layer 202 may be used for signal propagation throughout the semiconductor device 200, and a second interconnect layer 204 on an opposing second side of the device layer 202 may be used for power distribution in the semiconductor device 200.

The device layer 202 includes a substrate 206 of the semiconductor device 200. The substrate 206 may correspond to a portion of a semiconductor wafer on which the semiconductor device 200 is formed. The substrate 206 may include a silicon (Si) substrate, a substrate formed of a material including silicon, a III-V compound semiconductor material substrate such as gallium arsenide (GaAs), a silicon-on-insulator (SOI) substrate, or another type of substrate. The substrate 206 may extend in an x-direction and/or in a y-direction in the semiconductor device 200 such that the top and bottom surfaces of the substrate 206 are approximately orthogonal to the z-direction in the semiconductor device 200.

Integrated circuit devices 208 may be included in and/or on the substrate 206 in the device layer 202 of the semiconductor device 200. The integrated circuit devices 208 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receivers, optical circuits, and/or other types of front end semiconductor devices.

A front end transistor structure may include a plurality of source/drain regions, which may correspond to doped regions of the substrate 206, separated by a channel region in the substrate 206. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 210 is included over the substrate 206. The dielectric layer 210 includes an interlayer dielectric (ILD) layer, an etch stop layer (ESL), and/or another type of dielectric layer. The dielectric layer 210 includes dielectric material(s) that enable various portions of the substrate 206 and/or the integrated circuit devices 208 to be selectively etched or protected from etching, and/or to electrically isolate the integrated circuit devices 208 in the device layer 202. The dielectric layer 210 includes a silicon nitride (SiₓN_{y}), an oxide (e.g., a silicon oxide (SiOₓ) and/or another oxide material), and/or another type of dielectric material. The dielectric layer 210 may extend in the x-direction and/or in the y-direction in the semiconductor device 200. Contacts 212 (e.g., source/drain contacts, gate contacts) may extend through the dielectric layer 210 and between the integrated circuit devices 208 and the interconnect layer 204. The contacts may electrically connect the integrated circuit devices 208 to the interconnect layer 204. The contacts 212 may include vias, plugs, and/or another type of elongated electrically conductive structures. The contacts 212 may include tungsten (W), cobalt (Co), ruthenium (Ru), titanium (Ti), aluminum (Al), and/or gold (Au), among other electrically conductive materials.

The interconnect layer 204 includes a plurality of dielectric layers (e.g., back end dielectric layers) that are arranged in a direction (e.g., the z-direction) that is approximately perpendicular to the top surface of the substrate 206. The dielectric layers may include ILD layers 214 and ESLs 216 that are arranged in an alternating manner in the z-direction. The ILD layers 214 and the ESLs 216 may extend in the x-direction and/or in the y-direction in the semiconductor device 200.

The ILD layers 214 may each include a low dielectric constant (low-k) oxide material such as silicon oxide (SiOₓ) or undoped silicate glass (USG). Additionally and/or alternatively, the ILD layers 214 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 214 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 216 may each include a silicon nitride (SiₓN_{y}), silicon carbide (SiC), silicon oxynitride (SiON), and/or another suitable dielectric material. In some implementations, an ILD layer 214 and an ESL 216 include different dielectric materials to provide etch selectivity to enable various structures to be formed in the interconnect layer 204. For example, the ILD layers 214 may each include a low-k dielectric material such as USG, and the ESLs 216 may each include a high-k dielectric material such as silicon nitride (SiₓN_{y}) or silicon carbide (SiC). Additionally and/or alternatively, two or more ESLs 216 may include different materials. For example, one or more first ESLs 216 may include silicon nitride (SiₓN_{y}), and one or more second ESLs 216 may include silicon carbide (SiC).

The interconnect layer 204 includes a plurality of conductive structures that are arranged in a plurality of layers. The conductive structures may be electrically coupled and/or physically coupled with one or more of the integrated circuit devices 208 in the device layer 202. The conductive structures provide electrical routing that enables signals and/or power to be provided to and/or from the integrated circuit devices 208.

The layers of conductive structures may include a plurality of layers 218a-218e that are vertically arranged and alternate with a plurality of layers 220a-220d in the z-direction (e.g., vertically alternate). The layers 218a-218e each include a layer of metallization structures 222, and the layers 220a-220d each include a layer of interconnect structures 224.

The layers 218a-218e of metallization structures 222 may be referred to as M-layers. For example, a layer 218a of metallization structures 222 (referred to as a metal-0 (M0) layer) may be located at the bottom of the interconnect layer 204 and may be coupled to the device layer 202. In particular, the metallization structures 222 in the M0 layer may be coupled to the contacts 212 (e.g., a contact layer referred to as “CO”-layer) of the integrated circuit devices 208 in the device layer 202. A layer 218b of metallization structures 222 (referred to as a metal-1 layer (M1) layer) may be located above the layer 218a of metallization structures 222 in the interconnect layer 204, a layer 218c of metallization structures 222 (referred to as a metal-2 layer (M2) layer) may be located above a layer 218b of metallization structures 222, and so on.

A layer 220a of interconnect structures 224 (referred to as a via-1 (V0) layer) may be included between the M0 layer and the M1 layer to interconnect the M0 layer and the M1 layer, a layer 220b of interconnect structures 224 (referred to as a via-2 (V1) layer) may be included between the M1 layer and the M2 layer to interconnect the M1 layer and the M2 layer, and so on.

The metallization structures 222 may include a combination of trenches, metallization layers, conductive traces, and/or other types of conductive structures. The interconnect structures 224 may include a combination of vias, interconnects, and/or other types of conductive structures. The metallization structures 222 and the interconnect structures 224 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 204 and the metallization structures 222, and/or between the dielectric layers of the interconnect layer 204 and the interconnect structures 224. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 222, a topmost layer of interconnect structures 224) may be coupled to connection structures at the top of the semiconductor device 200. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 222, a topmost layer of interconnect structures 224) may be coupled to bonding structures, such as bonding pads and/or bonding vias.

As further shown in FIG. 2A, a trench capacitor structure 226 is included in the interconnect layer 204 of the semiconductor device 200. The trench capacitor structure 226 is an example structural implementation of the overflow capacitor 114 of the pixel sensor 100.

In general, a capacitor structure may include an MIM structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in a semiconductor device. A deep trench capacitor (DTC) is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure. The trench of a DTC structure is typically formed to have a high aspect ratio between the depth of the trench and the width of the trench.

Referring to FIG. 2A, the trench capacitor structure 226 may include a DTC structure that extends through and/or may be included in one or more dielectric layers in the interconnect layer 204, such as one or more ILD layers 214 and/or one or more ESLs 216. In some implementations, a trench capacitor structure 226 is configured to store a charge (e.g., a photocurrent) for an integrated circuit device 208 (e.g., a pixel sensor) in the semiconductor device 200. In some implementations, an integrated circuit device 208 is electrically coupled to a trench capacitor structure 226 to form a memory cell (e.g., a dynamic random access memory (DRAM) cell or another type of capacitor-based memory cell) in the semiconductor device 200. In some implementations, a trench capacitor structure 226 is configured to provide charge decoupling for one or more integrated circuit devices 208. In some implementations, a trench capacitor structure 226 is configured to perform another function in the semiconductor device 200.

The trench capacitor structure 226 may be electrically coupled and/or physically coupled to a bottom contact 228 at a bottom of the trench capacitor structure 226, and to a top contact 230 at a top of the trench capacitor structure 226. Alternatively, the trench capacitor structure 226 may be electrically coupled and/or physically coupled to a plurality of top contacts at the top of the trench capacitor structure 226. The bottom contact 228 and the top contact 230 may each include one or more conductive structures in the interconnect layer 204, such as one or more metallization structures 222 and/or one or more interconnect structures 224, among other examples.

FIG. 2B illustrates a detailed cross-section view of the trench capacitor structure 226. As shown in FIG. 2B, the trench capacitor structure 226 includes one or more trenches 232 on the bottom contact 228. The bottom contact 228 may be included in an ILD layer 214a in the interconnect layer 204 of the semiconductor device 200. A trench 232 of the trench capacitor structure 226 may extend through one or more dielectric layers in the interconnect layer 204 of the semiconductor device 200, including through an ESL 216a, an ILD layer 214a, an ESL 216b, an ILD layer 214c, an ESL 216c, and/or an ILD layer 214d, among other examples. In some implementations, the trench(es) 232 may have a high aspect ratio, which is a ratio of a depth (or height) of the trench(es) 232 to a lateral width (or critical dimension) of the trench(es) 232. Thus, the trench capacitor structure 226 may be referred to as a DTC structure. In some implementations, the aspect ratio of a trench 232 may be approximately 10:1 or greater. In some implementations, a trench 232 may have an aspect ratio that is included in the range of approximately 20:1 to approximately 50:1. However, other values and ranges are within the scope of the present disclosure.

As further shown in FIG. 2B, the trench capacitor structure 226 includes a plurality of conformal layers that conform to the profile of the trench(es) 232. The conformal layers may include an adhesion layer 234, a bottom electrode layer 236 on the adhesion layer 234, and an insulator layer 238 on the bottom electrode layer 236. The adhesion layer 234, the bottom electrode layer 236, and the insulator layer 238 may each conform to the profile of the trench(es) 232 such that the adhesion layer 234, the bottom electrode layer 236, and the insulator layer 238 conform to the sidewalls and the bottom surfaces of the trench(es) 232.

As shown in the enlarged rectangular portion A, the insulator layer 238 includes a stacked insulator structure of first type dielectric layers 240-1, 240-2, and 240-3, and second type dielectric layers 242-1 and 242-2. The first type dielectric layers 240-1, 240-2, and 240-3 are alternately arranged with the second type dielectric layers 242-1 and 242-2 to form an insulator layer stack. In some implementations, the first type dielectric layers 240-1, 240-2, and 240-3 are each a layer of aluminum oxide (AlₓO_{y} such as Al₂O₃), and the second type dielectric layers 242-1 and 242-2 are each a layer of zirconium oxide (ZrOₓ such as ZrO₂), so that the insulator layer 238 is a dielectric layer stack that includes alternating layers of aluminum oxide and zirconium oxide.

Unlike some MIM capacitors that include a ZAZ-based insulator layer (e.g., where the outer layers are zirconium oxide layers), the insulator layer 238 of the capacitor structure 226 includes at least one outer aluminum oxide layer. In particular, the first type dielectric layer 240-1 at the bottom of the dielectric layer stack of the insulator layer 238 may be an aluminum oxide layer. In some implementations, the dielectric layer stack of the insulator layer 238 includes top and bottom aluminum oxide layers. In other words, the first type dielectric layers 240-1 and 240-3 respectively at the bottom and the top of the dielectric stack of the insulator layer 238 are aluminum oxide layers, and at least one inner layer (e.g., the second type dielectric layer 242-1, the second type dielectric layer 242-2) between the outer aluminum oxide layers may be a zirconium oxide layer (or another high dielectric constant dielectric layer having a higher dielectric constant than aluminum oxide). In the example illustrated in the enlarged rectangular portion A in FIG. 2B, the dielectric stack of the insulator layer 238 is an Al₂O₃/ZrO₂/Al₂O₃/ZrO₂/Al₂O₃ (AZAZA) dielectric layer stack. However, other implementations within the scope of the present disclosure include other combinations of aluminum oxide and zirconium oxide layers. For example, the dielectric stack of the insulator layer 238 may include an Al₂O₃/ZrO₂/Al₂O₃ (AZA) dielectric layer stack, an Al₂O₃/ZrO₂/Al₂O₃/ZrO₂/Al₂O₃/ZrO₂/Al₂O₃ (AZAZAZA) dielectric layer stack, and/or other quantities of alternating aluminum oxide layers and zirconium oxide layers where the outermost (e.g., top and bottom) layers of the insulator layer 238 are aluminum oxide layers.

Since the outermost (e.g., top and/or bottom) layers (e.g., the first type dielectric layers 240-1 and/or 240-3) of the insulator layer 238 are aluminum oxide layers, interlayers between the insulator layer 238 and the bottom electrode layer 236 and/or between the insulator layer 238 and a top electrode layer 244 of the trench capacitor structure 226 may be omitted, enabling a greater total capacitance to be achieved for the trench capacitor structure 226. The interlayers may be omitted in that the aluminum oxide of the outermost (e.g., top and bottom) layers (e.g., the first type dielectric layers 240-1 and 240-3) of the insulator layer 238 are able to better withstand oxygen dislocation (and therefore, are able to better withstand oxygen migration) than other types of high dielectric constant dielectric materials, such as zirconium oxide. Thus, the aluminum oxide of the outermost (e.g., top and bottom) layers (e.g., the first type dielectric layers 240-1 and 240-3) of the insulator layer 238 is less susceptible to charge trapping. In this way, lower dielectric constant materials, such as titanium oxynitride (TiOₓN_{y}), that might otherwise be included as the interlayer(s), are omitted, thereby enabling a higher overall dielectric constant to be achieved between the bottom electrode layer 236 and the top electrode layer 244 (and thus, a higher overall capacitance may be achieved for the trench capacitor structure 226).

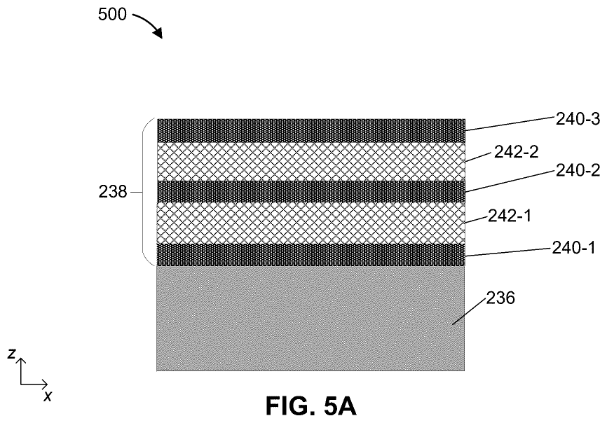

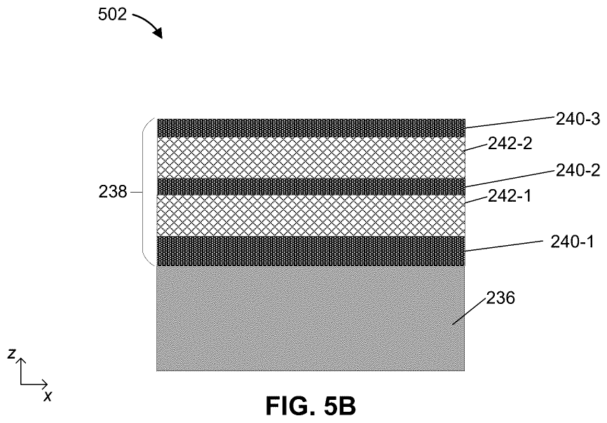

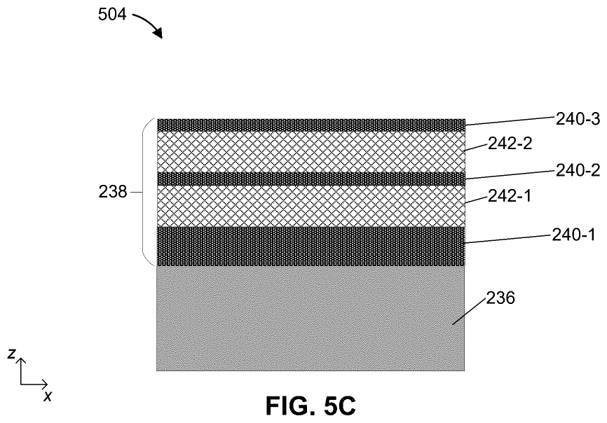

At least one inner layer (e.g., the second type dielectric layer 242-1, the second type dielectric layer 242-2) between the outer aluminum oxide layers may be a zirconium oxide layer or another high dielectric constant dielectric layer having a higher dielectric constant than aluminum oxide to enable a high capacitance to be achieved for the trench capacitor structure 226. While the zirconium oxide of the second type dielectric layer 242-1 and/or the second type dielectric layer 242-2 may be more susceptible to oxygen dislocation than the aluminum oxide of the first type dielectric layers 240-1, 240-2, and/or 240-3, the aluminum oxide of the first type dielectric layers 240-1 and 240-3 (e.g., the outer aluminum oxide layers) may inhibit dislocated oxygen from migrating to the bottom electrode layer 236 and/or to the top electrode layer 244. As described in greater detail in connection with FIGS. 5A-5C, the thicknesses of the second type dielectric layer 242-1 and/or of the second type dielectric layer 242-2 may be greater than the thicknesses of the first type dielectric layers 240-1, 240-2, and/or 240-3 to enable a higher capacitance to be achieved for the trench capacitor structure 226 while enabling a low amount of charge trapping to be achieved in the insulator layer 238.

The first type dielectric layers 240-1, 240-2, and 240-3 and the second type dielectric layers 242-1 and 242-2 each conform to the profile of the trench(es) 232 (e.g., to the sidewalls and the bottom surfaces of the trench(es) 232) such that the dielectric layer 240-1 is an outer layer of the dielectric layer stack formed on the bottom electrode layer 236, the dielectric layer 242-1 is formed on the dielectric layer 240-1, the dielectric layer 240-2 is formed on the dielectric layer 242-1, the dielectric layer 242-2 is formed on the dielectric layer 240-2, and the dielectric layer 240-3 is another outer layer of the dielectric stack formed on the dielectric layer 242-2. In some implementations, the dielectric layer 240-1 is directly formed on (e.g., abuts or is in direct physical contact with) the bottom electrode layer 236 and adjacent ones of the first type dielectric layers 240-1, 240-2, and 240-3 and the second type dielectric layers 242-1 and 242-2 are directly formed on each other. Bottom surfaces of the dielectric layer 240-1 physically contact top surfaces of the bottom electrode layer 236.

The trench capacitor structure 226 further includes a top electrode layer 244 on the insulator layer 238. In some implementations, the top electrode layer 244 is a fill layer that fills in the remaining areas of the trench(es) 232. Alternatively, the top electrode layer 244 may also be a conformal layer that conforms to the sidewalls and the bottom surfaces of the trench(es) 232, and a dielectric plug layer or fill layer is further included in the remaining areas of the trench(es) 232. As shown in the enlarged rectangular portion A, the top electrode layer 244 is adjacent to the dielectric layer 240-3. In more detail, the top electrode layer 244 is formed on the dielectric layer 240-3 of the insulator layer stack. In some implementations, the top electrode layer 244 is directly formed on (e.g., abuts or is in direct physical contact with) the dielectric layer 240-3, where bottom surfaces of the top electrode layer 244 physically contact top surfaces of the dielectric layer 240-3.

The adhesion layer 234 may also be referred to as a glue layer, and may be included to promote adhesion of the bottom electrode layer 236 to the dielectric layers (e.g., the ILD layers 214b, 214c, and 214d, the ESLs 216a, 216b, and 216c) and/or to the bottom contact 228. The adhesion layer 234 may also act as a barrier layer that prevents upward migration of an electrically conductive material (e.g., copper (Cu)) of the bottom contact 228 into the bottom electrode layer 236. The adhesion layer 234 may include tantalum (Ta), tantalum nitride (TaN), and/or another suitable adhesion material.

The bottom electrode layer 236, the insulator layer 238, and the top electrode layer 244 correspond to an MIM structure of the trench capacitor structure 226. Thus, the trench capacitor structure 226 may also be referred to as an MIM capacitor structure. The bottom electrode layer 236 (also referred to as a capacitor bottom metal (CBM)) and the top electrode layer 244 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 236 and the top electrode layer 244 include the same material or the same material composition. In some implementations, the bottom electrode layer 236 and the top electrode layer 244 include different materials or different material compositions.

In some implementations, the trench capacitor structure 226 includes a plurality of trenches 232, and the MIM structure of the trench capacitor structure 226 (e.g., the bottom electrode layer 236, the insulator layer 238, and the top electrode layer 244) may extend along the sidewalls and bottom surfaces of the plurality of trenches 232, and between the plurality of trenches 232. The trenches 232 may be laterally arranged and spaced apart by a distance (indicated in FIG. 2B as dimension D1) in the x-direction. In this way, including a plurality of trenches 232 in the trench capacitor structure 226 enables the length (and therefore the area) of the MIM structure of the trench capacitor structure 226 (e.g., of the bottom electrode layer 236, the insulator layer 238, and the top electrode layer 244) to be extended, thereby increasing the capacitance of the trench capacitor structure 226.

As further shown in FIG. 2B, the trench capacitor structure 226 may include one or more capping layers above the trench(es) 232 and above the MIM structure of the trench capacitor structure 226. The one or more capping layers may include an oxide capping layer 246, an oxynitride capping layer 248, and/or a nitride capping layer 250, among other examples. The capping layers may provide electrical isolation for the MIM structure of the trench capacitor structure 226, and/or may also function as a hard mask layer stack for forming the top contact 230. The oxide capping layer 246 may include an oxide-containing dielectric material such as silicon oxide (SiOₓ such as SiO₂), among other examples. The oxynitride capping layer 248 may include an oxynitride-containing dielectric material such as silicon oxynitride (SiON), among other examples. The nitride capping layer 250 may include a nitride-containing dielectric material such as silicon nitride (SiₓN_{y} such as Si₃N₄), among other examples.

As further shown in FIG. 2B, the trench capacitor structure 226 may include one or more sidewall spacers 252 and/or 254 on the sidewalls of the capping layers 246-250 and/or on sidewalls of the top electrode layer 244 that is above the trench(es) 232. The combination of the capping layers 246-250 and the sidewall spacers 252 and 254 may be used as a self-aligned mask when etching the adhesion layer 234, the bottom electrode layer 236, the insulator layer 238, and/or the top electrode layer 244 to define the MIM structure of the trench capacitor structure 226. The sidewall spacer 252 may include an oxide-containing dielectric material such as silicon oxide (SiOₓ such as SiO₂), among other examples. The sidewall spacer 254 may include a nitride-containing dielectric material such as silicon nitride (SiₓN_{y} such as Si₃N₄), among other examples.

FIG. 2C is similar to FIG. 2B except that it includes one first type dielectric layer 240, and one second type dielectric layer 242 on the first type dielectric layer 240 to form an insulator layer stack. In some implementations, the first type dielectric layer 240 is a layer of aluminum oxide (AlₓO_{y} such as Al₂O₃), and the second type dielectric layer is a layer of zirconium oxide (ZrOₓ such as ZrO₂), so that the insulator layer 238 is a dielectric layer stack that includes a layer of aluminum oxide and a layer of zirconium oxide. The benefits of the interlayer free aluminum oxide can be achieved with the arrangement of a first type dielectric layer 240 and a second type dielectric layer 242 in FIG. 2C.

As indicated above, FIGS. 2A-2C are provided as an example. Other examples may differ from what is described with regard to FIGS. 2A-2C.

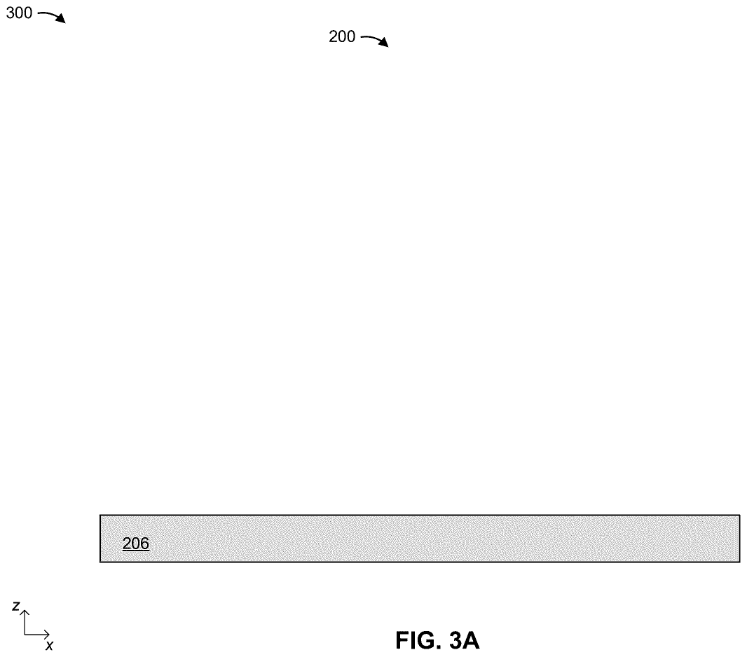

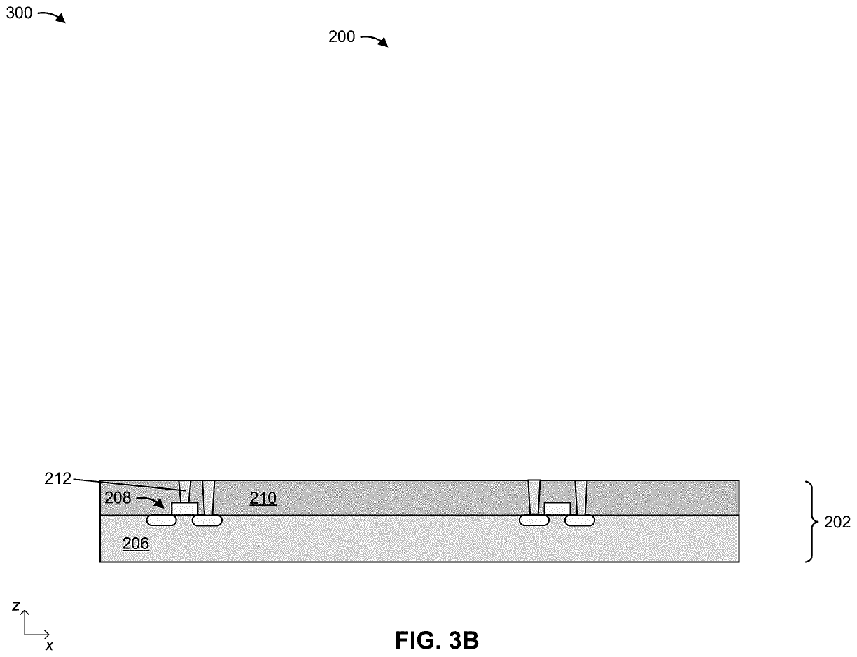

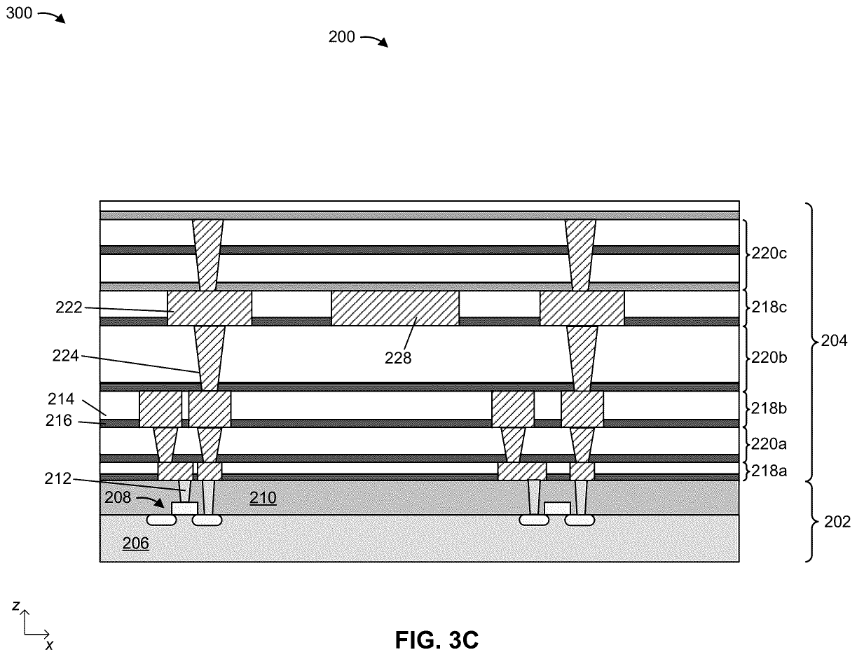

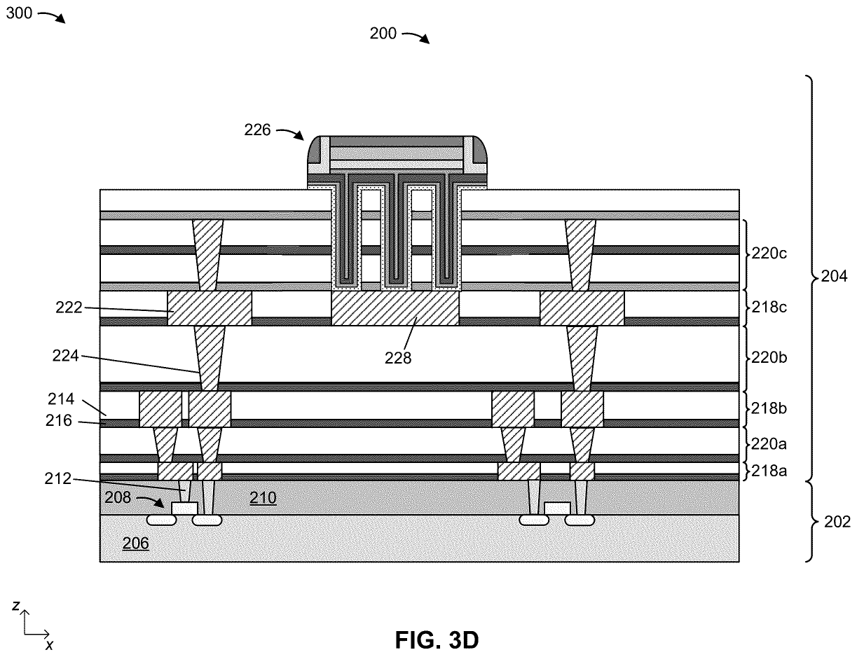

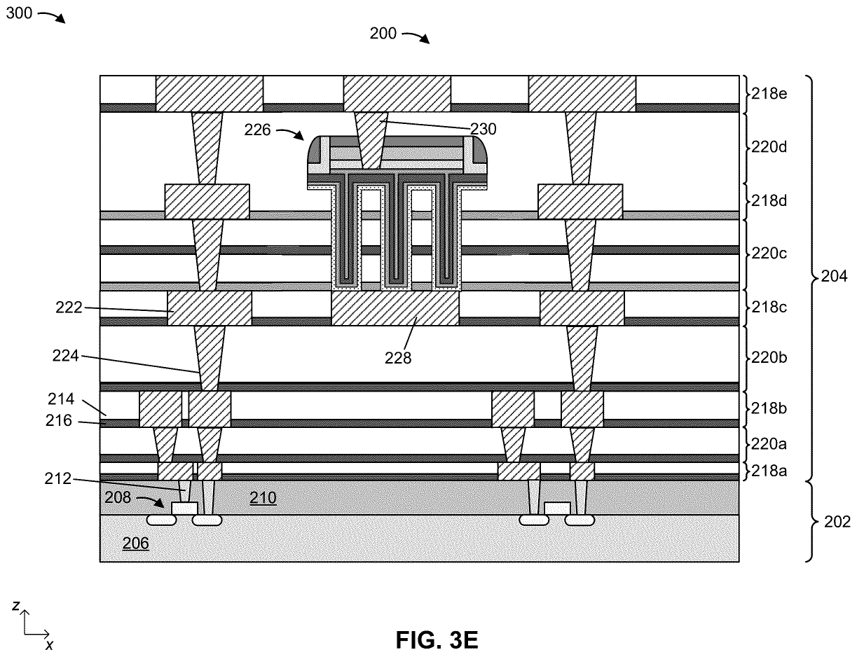

FIGS. 3A-3E are diagrams of an example implementation 300 of forming the semiconductor device 200 described herein. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 3A, the substrate 206 is provided. The substrate 206 may be provided in the form of a semiconductor wafer such as a silicon (Si) wafer, an SOI wafer, and/or another type of semiconductor work piece. The semiconductor device 200 may be formed on the semiconductor wafer with other semiconductor devices.

As shown in FIG. 3B, the integrated circuit devices 208 may be formed in and/or on the substrate 206 in the device layer 202 of the semiconductor device 200. One or more semiconductor processing tools may be used to form one or more portions of the integrated circuit devices 208. For example, an ion implantation tool may be used to dope one or more regions in the substrate 206 with one or more types of dopants to form well regions, implant regions, and/or other types of doped regions in the substrate 206 for the integrated circuit devices 208. As another example, a deposition tool may be used to perform various deposition operations to deposit layers and/or structures of the integrated circuit devices 208, and/or to deposit photoresist layers for etching the substrate 206 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 206 and/or portions of the deposited layers to form the integrated circuit devices 208. As another example, a planarization tool may be used to planarize portions of the integrated circuit devices 208. As another example, a plating tool may be used to deposit metal structures and/or layers of the integrated circuit devices 208.

As further shown in FIG. 3B, a deposition tool is used to deposit the dielectric layer 210 over and/or on the substrate 206 and over and/or on the integrated circuit devices 208. A deposition tool may be used to deposit the dielectric layer 210 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 210 after the dielectric layer 210 is deposited.

As further shown in FIG. 3B, the contacts 212 of the integrated circuit devices 208 may be formed through the dielectric layer 210. The contacts 212 may be formed in recesses in the dielectric layer 210. In some implementations, a pattern in a photoresist layer is used to etch the dielectric layer 210 to form the recesses. In these implementations, a deposition tool may be used to form the photoresist layer on the dielectric layer 210. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 210 based on a pattern to form the recesses.

The contacts 212 may be formed in the recesses. In some implementations, a contact 212 (e.g., a gate contact) is formed on a gate structure of an integrated circuit device 208. In some implementations, a contact 212 (e.g., a source/drain contact) is formed on a source/drain region of an integrated circuit device 208. A deposition tool may be used to deposit the material of the contacts 212 in the recesses using a CVD technique, a PVD technique, an ALD technique, an electroplating technique, and/or another suitable deposition technique. The material of the contacts 212 may be deposited in one or more deposition operations. In some implementations, a seed layer is first deposited, and the material of the contacts 212 is deposited on the seed layer. In some implementations, a planarization tool is used to perform a planarization operation (e.g., a CMP operation) to planarize the contacts 212 after the contacts 212 are deposited such that the tops of the contacts 212 are approximately co-planar with the top of the dielectric layer 210.

As shown in FIG. 3C, a first portion of the interconnect layer 204 of the semiconductor device 200 is formed above the dielectric layer 210. One or more deposition tools are used to deposit alternating layers of ILD layers 214 and ESLs 216 in the first portion of the interconnect layer 204 of the semiconductor device 200. In this way, the ILD layers 214 and ESLs 216 may be arranged in the z-direction in the semiconductor device 200. One or more deposition tools may be used to deposit each of the ILD layers 214 and each of the ESLs 216 using a PVD technique, an ALD technique, a CVD technique, an oxidation technique, and/or another suitable deposition technique. In some implementations, a planarization tool may be used to planarize the ILD layers 214 and/or the ESLs 216 after the ILD layers 214 and/or the ESLs 216 are deposited.

As further shown in FIG. 3C, a deposition tool, an exposure tool, a developer tool, an etch tool, a planarization tool, a plating tool, and/or another semiconductor processing tool may be used to perform various operations to form the metallization structures 222 and to form the interconnect structures 224 in the first portion of the interconnect layer 204 of the semiconductor device 200. The bottom contact 228 of the trench capacitor structure 226 may also be formed in the first portion of the interconnect layer 204.

In some implementations, the first portion of the interconnect layer 204 may be formed in a plurality of layers. For example, an ILD layer 214 and an ESL 216 may be formed (e.g., using one or more deposition tools and/or one or more planarization tools), recesses may be formed in and/or through the ILD layer 214 and the ESL 216 (e.g., using an exposure tool, a developer tool, and/or an etch tool), and the layer 218a (e.g., the M0 layer) of metallization structures 222 may be formed in the ILD layer 214 and the ESL 216 (e.g., using one or more deposition tools and/or one or more planarization tools). Another ILD layer 214 and another ESL 216 may be formed, and the layer 220a (e.g., the V0 layer) of interconnect structures 224 may be formed in the ILD layer 214 and the ESL 216. The layers 218b, 218c, 220b, and 220c may be formed in a similar manner.

One or more deposition tools may be used to deposit the metallization structures 222, the interconnect structures 224, and/or the bottom contact 228 using a PVD technique, an ALD technique, a CVD technique, an electroplating technique (e.g., an electro-chemical plating technique), and/or another suitable deposition technique. In some implementations, a planarization tool may be used to planarize the metallization structures 222, the interconnect structures 224, and/or the bottom contact 228 after the metallization structures 222, the interconnect structures 224, and/or the bottom contact 228 are deposited.

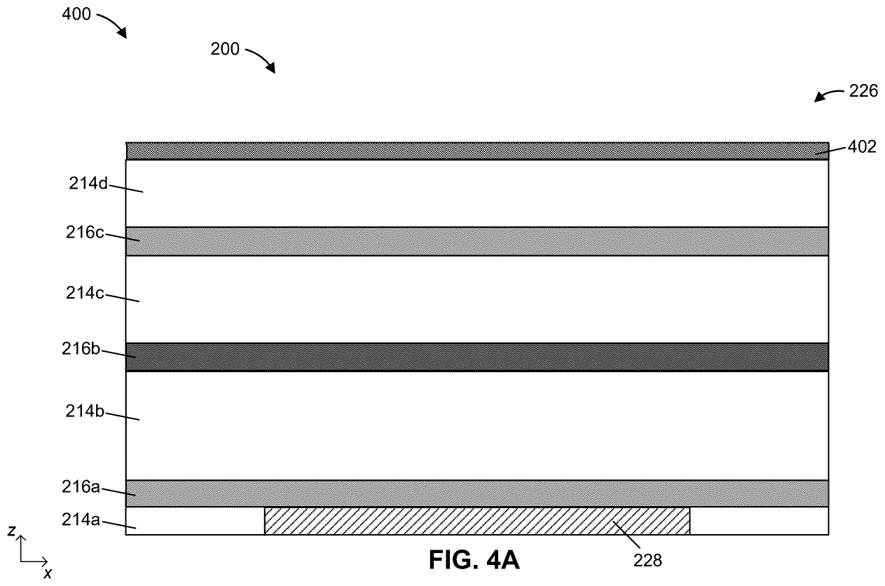

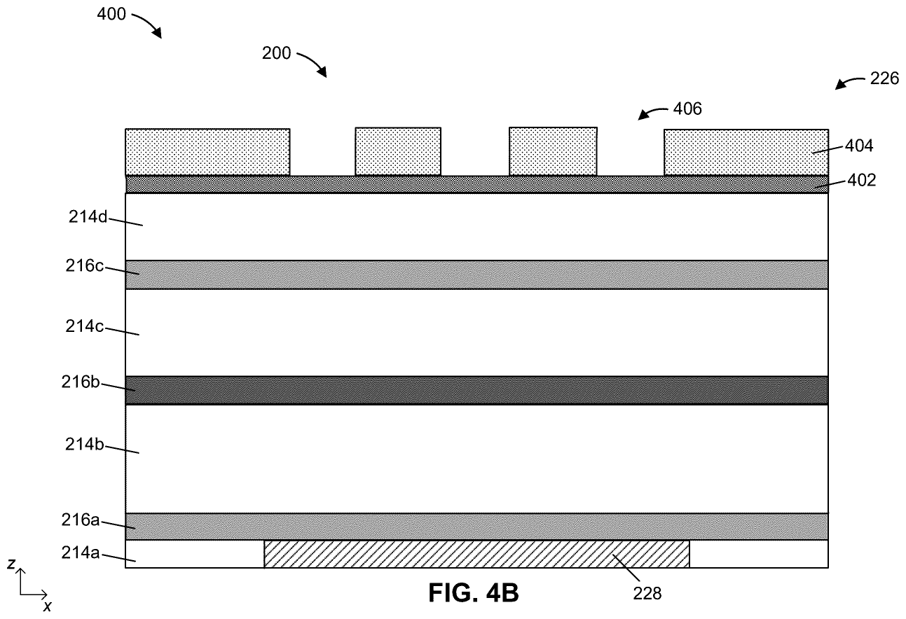

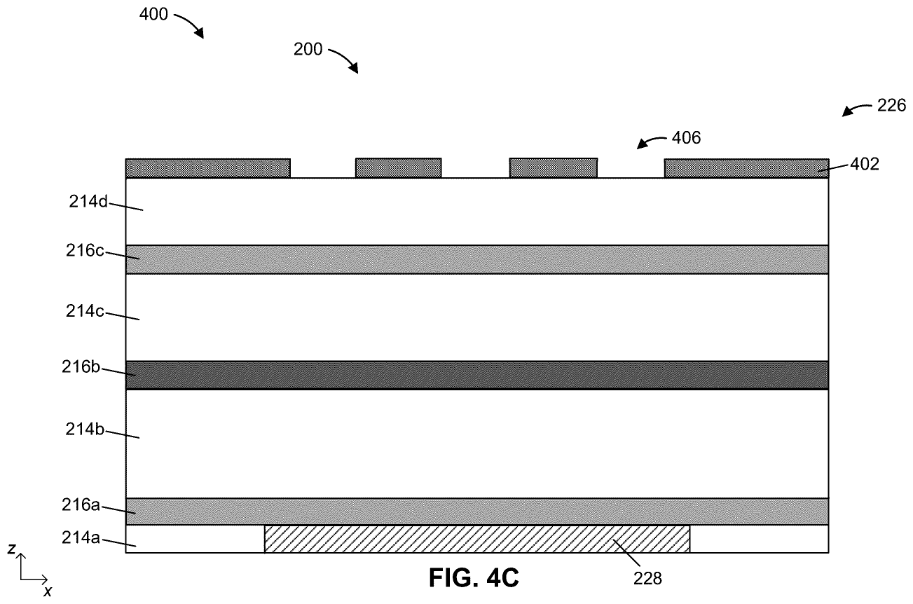

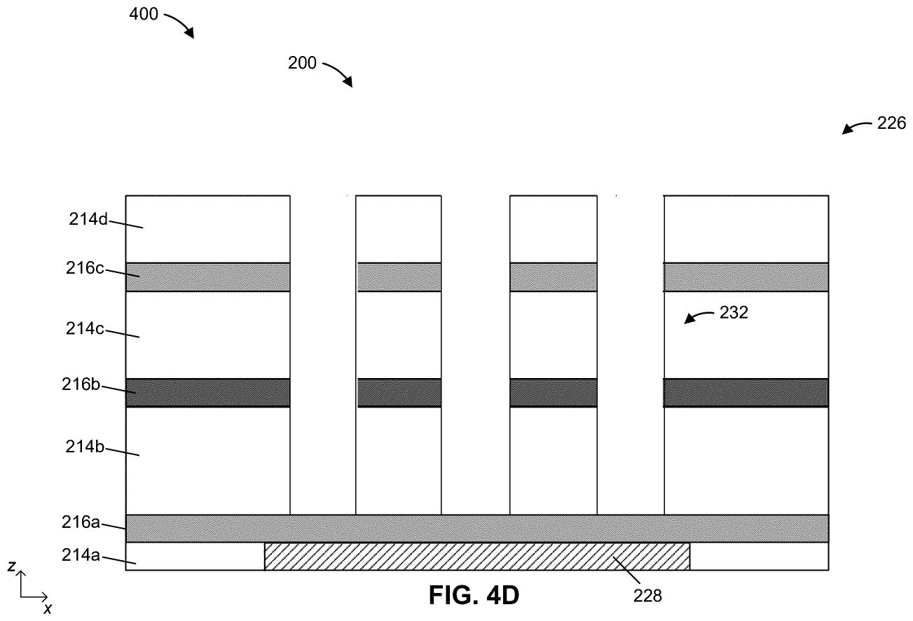

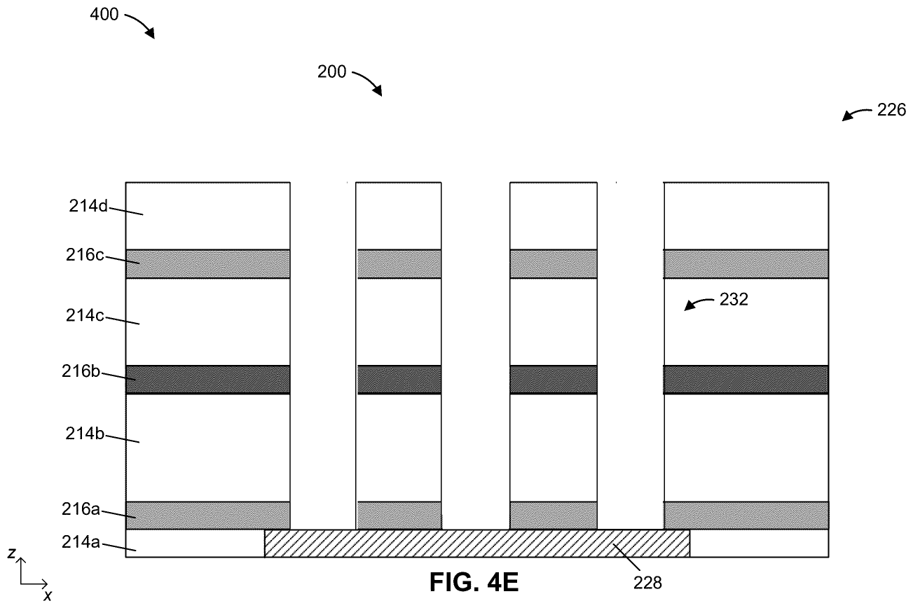

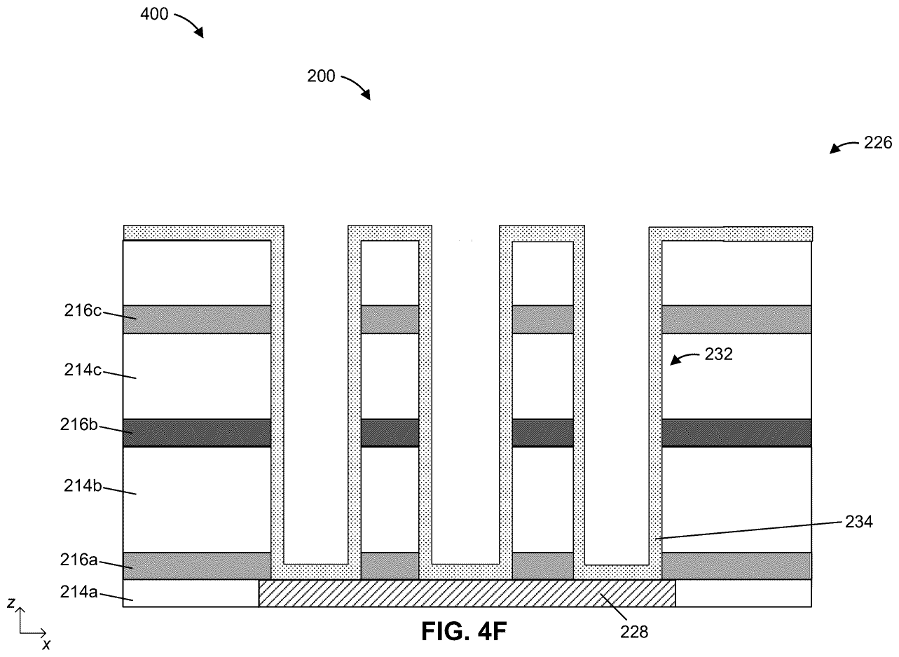

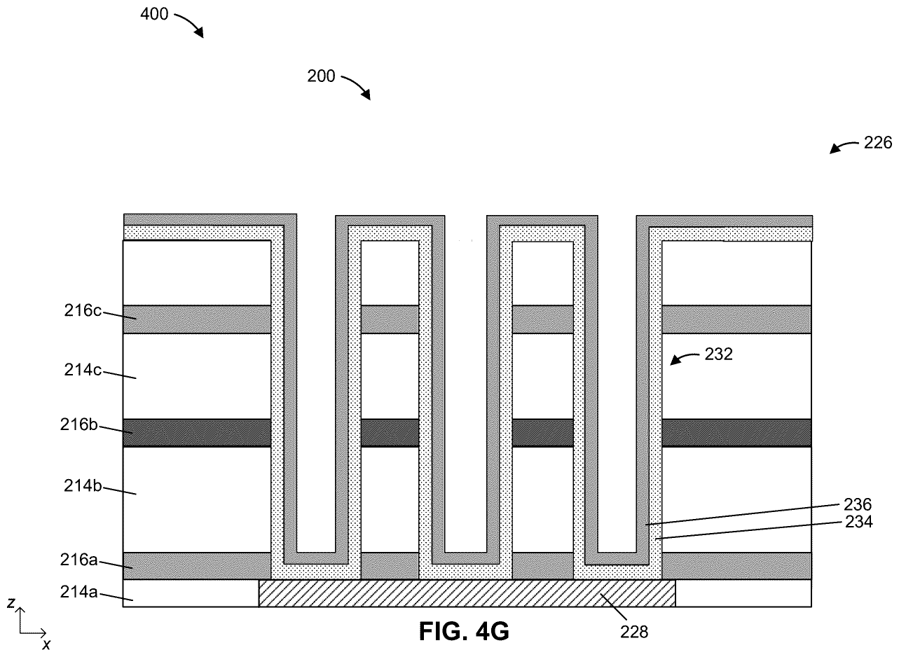

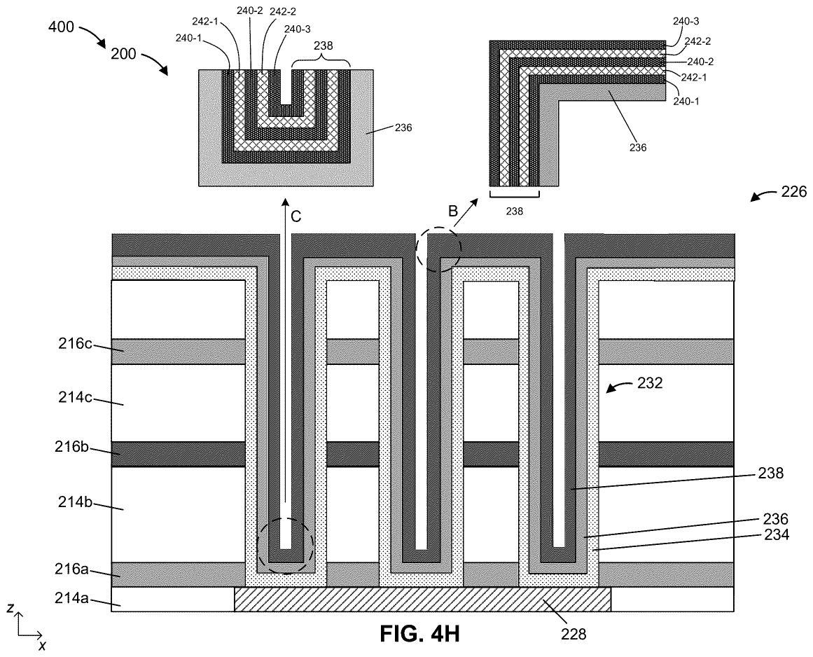

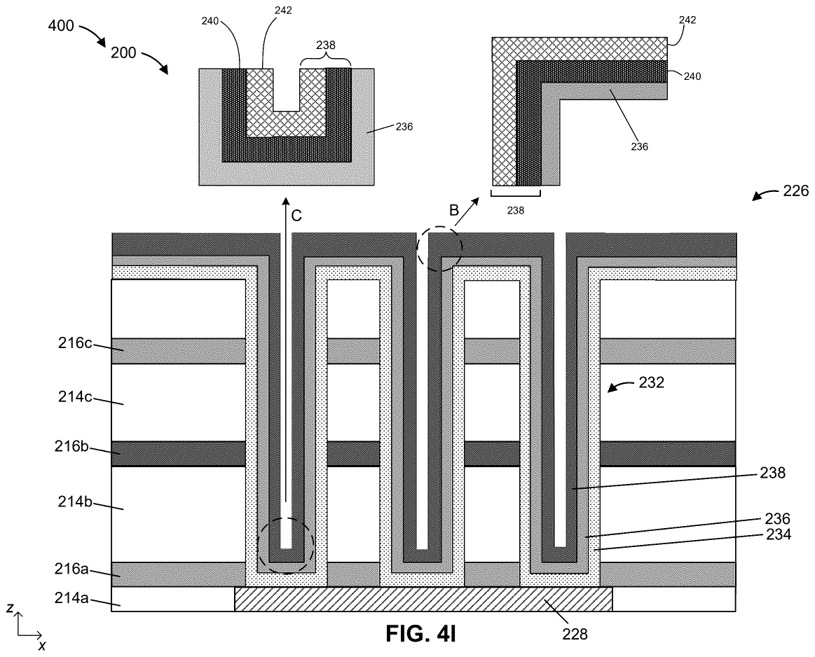

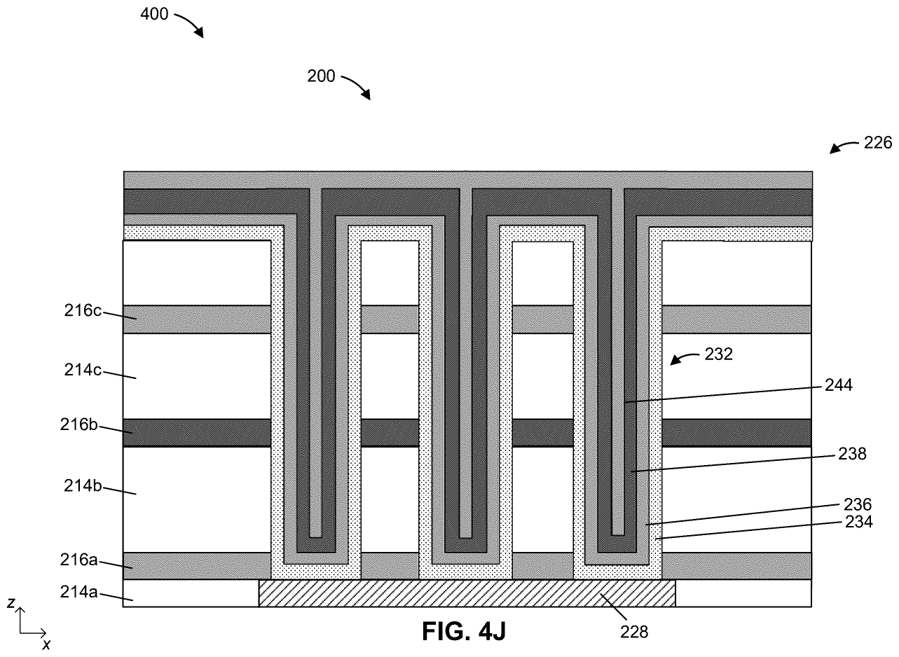

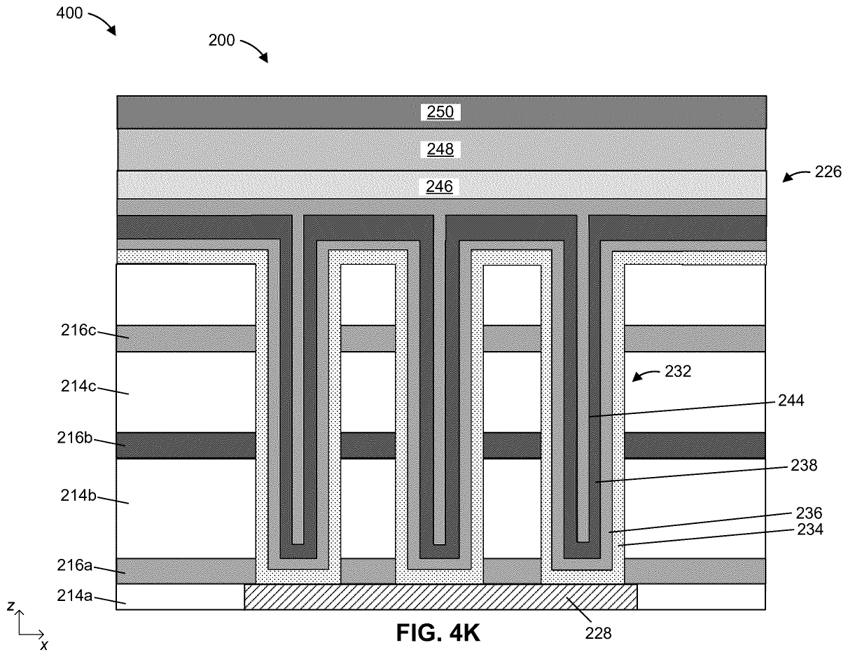

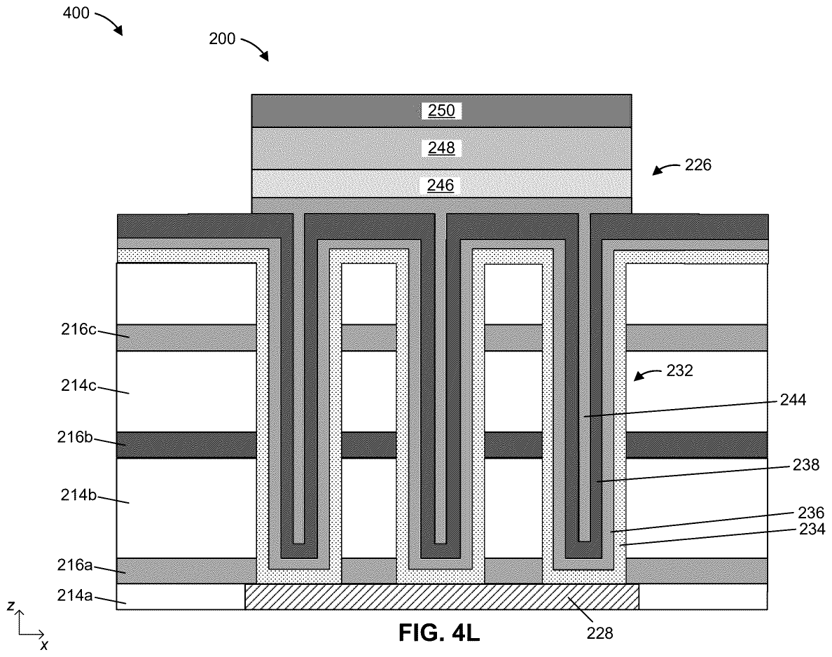

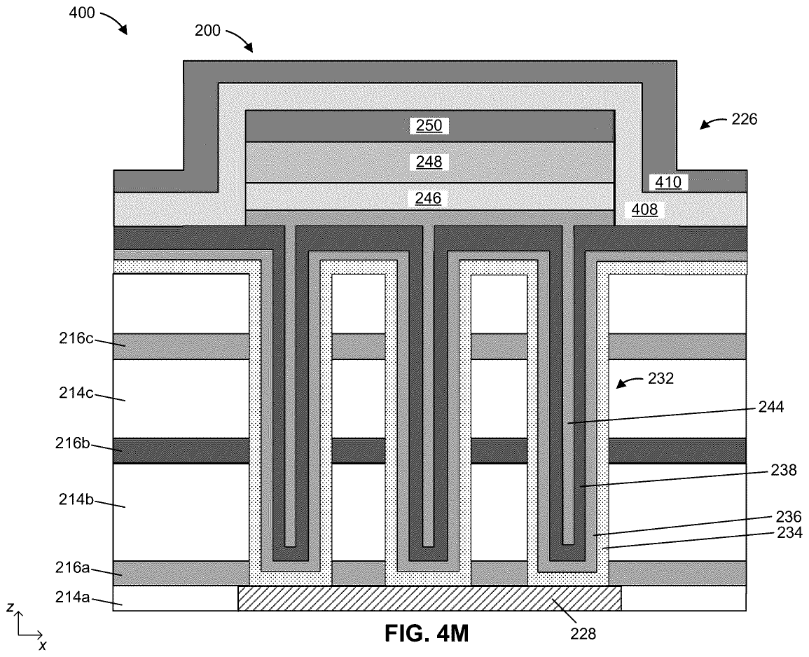

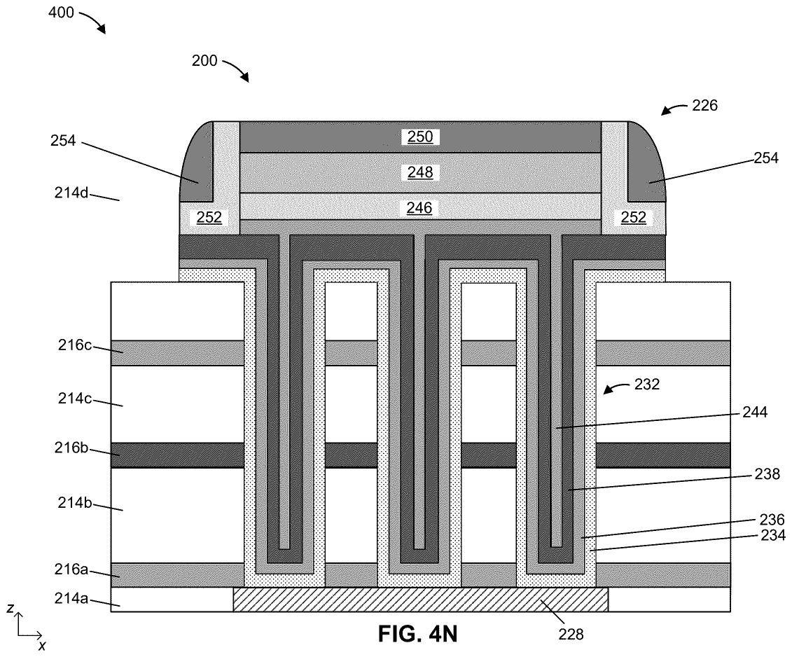

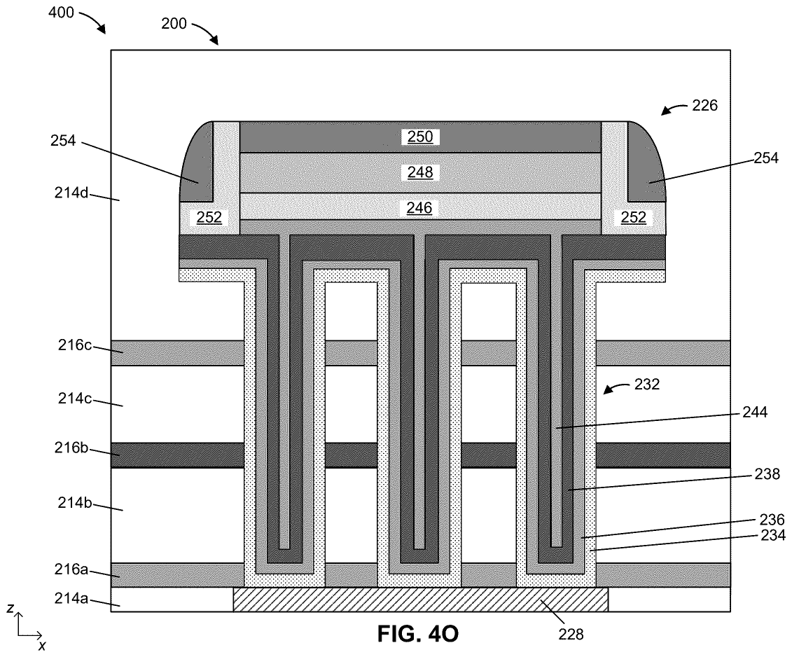

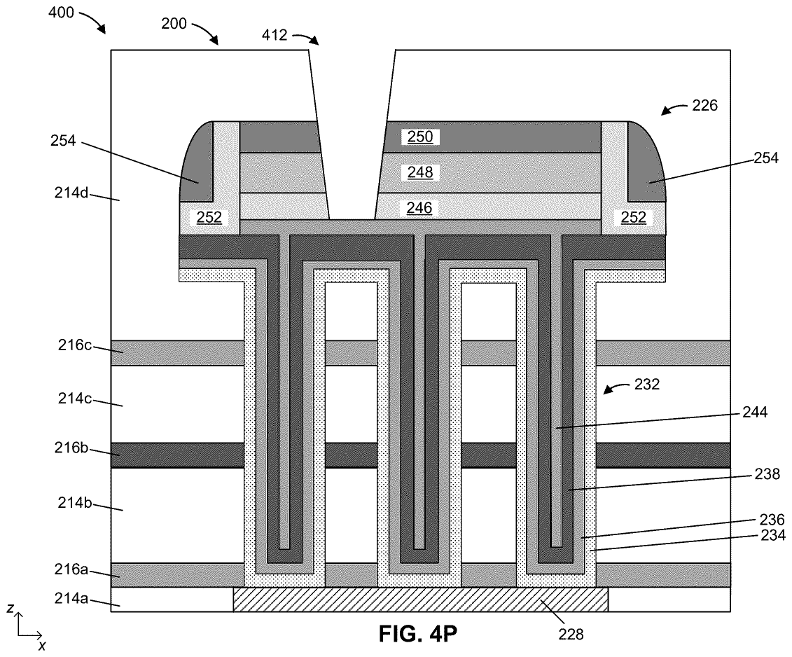

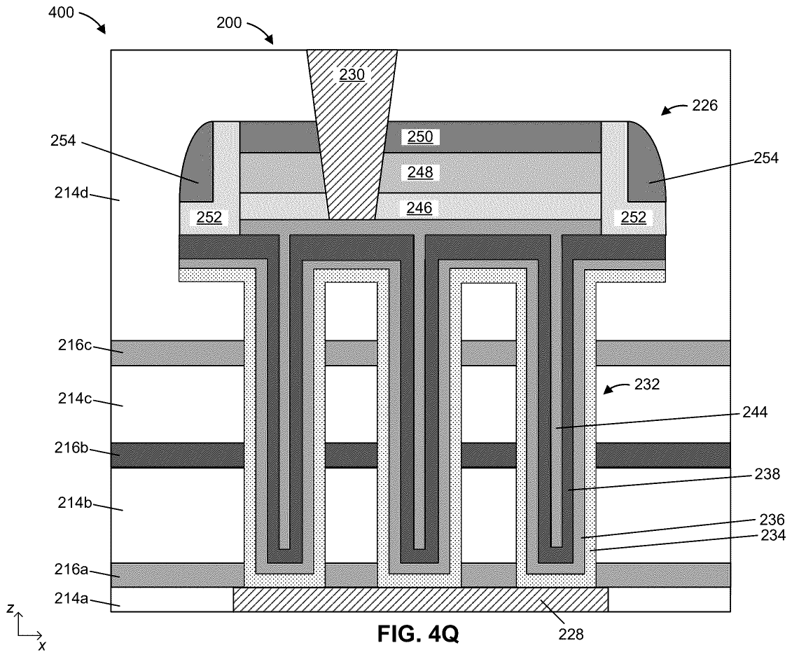

As shown in FIG. 3D, a trench capacitor structure 226 may be formed in one or more dielectric layers in the interconnect layer 204. The trench capacitor structure 226 may be formed such that the trench(es) 232 of the trench capacitor structure 226 land on the bottom contact 228 in the interconnect layer 204. An example process for forming the trench capacitor structure 226 is illustrated and described in connection with FIGS. 4A-4Q.

As shown in FIG. 3E, a second portion of the interconnect layer 204 of the semiconductor device 200 is formed above the first portion of the interconnect layer 204, including above the trench capacitor structure 226. The second portion of the interconnect layer 204 may be formed in a similar manner as the first portion of the interconnect layer 204, as described in connection with FIG. 3C. The top contact 230 of the trench capacitor structure 226 may be formed in the second portion of the interconnect layer 204.

As indicated above, FIGS. 3A-3E are provided as an example. Other examples may differ from what is described with regard to FIGS. 3A-3E.

FIGS. 4A-4Q are diagrams of an example implementation 400 of forming a trench capacitor structure 226 described herein. In some implementations, one or more of the semiconductor processing operations described in connection with FIGS. 4A-4Q may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 4A-4Q may be performed as part of the process for forming the semiconductor device 200 described in connection with FIGS. 3A-3E.

As shown in FIG. 4A, masking layers may be formed on the ILD layer 214d in the interconnect layer 204 of the semiconductor device 200. For example, a dielectric masking layer 402 may be formed on the ILD layer 214d. The dielectric masking layer 402 may include a silicon oxynitride material (SiON) and/or another suitable dielectric material.

A deposition tool may be used to deposit the dielectric masking layer 402 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 402 after the dielectric masking layer 402 is deposited.

As shown in FIG. 4B, a photoresist layer 404 may be formed above the dielectric masking layer 402, and a pattern 406 may be formed in the photoresist layer 404. A deposition tool may be used to form the photoresist layer on the dielectric masking layer 402 (e.g., using a spin-coating technique or another suitable deposition technique). In some implementations, a bottom antireflective coating (BARC) is first deposited on the dielectric masking layer 402, and then the photoresist layer 404 is deposited onto the BARC. An exposure tool may be used to expose the photoresist layer 404 to a radiation source to pattern the photoresist layer 404. A developer tool may be used to develop and remove portions of the photoresist layer 404 to expose the pattern 406.

As shown in FIG. 4C, an etch tool may be used to etch the dielectric masking layer 402 based on the pattern 406 in the photoresist layer 404, to transfer the pattern 406 to the dielectric masking layer 402. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 402 compared to the material of the underlying ILD layer 214d. Thus, the etch operation may stop on the ILD layer 214d with minimal etching to the ILD layer 214d.

As shown in FIG. 4D, another etch operation is performed to etch through the ILD layers 214b, 214c, 214d, and through the ESLs 216b and 216c to form the trench(es) 232 of the trench capacitor structure 226. The etch operation may include, for example, a gas-based etch operation in which a different type of etchant is used, as compared to the etchant that was used to transfer the pattern 406 to the dielectric masking layer 402. Thus, the semiconductor device 200 may be transferred from a first etch tool (in which the pattern 406 was transferred to the dielectric masking layer 402) to a second etch tool (in which the ILD layers 214b, 214c, 214d, and the ESLs 216b and 216c are etched) using a wafer/die transport tool to reduce the likelihood of cross-contamination between the first and second etch tools. Alternatively, an etch tool that has multiple processing chambers (e.g., a cluster tool) may be used, and the semiconductor device 200 may be transferred between processing chambers of the etch tool for etching using different types of etchants.

The gas-based etchant that is used to etch the ILD layers 214b, 214c, 214d, and the ESLs 216b, 216c, may include a fluorine-based gas etchant that has a higher etch rate for the dielectric materials of the ILD layers 214b, 214c, 214d, and the ESLs 216b, 216c, compared to the etch rate of the dielectric masking layer 402. This enables the ILD layers 214b, 214c, 214d, and the ESLs 216b, 216c, to be etched with minimal etching to the dielectric masking layer 402 (and thus, minimal to no increase in the width or critical dimension at the tops of the trench(es) 232). The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the trench(es) 232 of the trench capacitor structure 226. For example, a first etch operation (referred to as a “main etch” operation) may be performed to form the trench(es) 232 to the ESL 216a. In other words, etching in the first etch operation stops at the ESL 216a such that the ESL 216a remains between the bottom of the trench(es) 232 and the underlying bottom contact 228. The ESL 216a is kept over the bottom contact 228 to prevent the bottom contact 228 from being exposed to oxygen and other contaminants that might otherwise result in oxidation of the bottom contact 228. After the first etch operation, the trench(es) 232 may have tapered sidewalls, resulting in the lateral width of the trench(es) 232 decreasing from the tops of the trench(es) 232 to the bottoms of the trenches.

A second etch operation (referred to as an “over etch” operation) may be performed after the first etch operation to shape the bottom portions of the trench(es) 232. In particular, the second etch operation may be performed to increase the verticality of the sidewalls of the trench(es) 232, thereby lessening the taper in the sidewalls of the trench(es) 232. The dielectric masking layer 402 remains on the ILD layer 214d during the first and second etch operations to form and shape the trench(es) 232 such that the dielectric masking layer 402 protects the ILD layer 214d from being etched, which reduces the likelihood of critical dimension widening and reduces the likelihood of corner rounding at the tops of the trench(es) 232.

As shown in FIG. 4E, a third etch operation (referred to as a “linear removal” etch operation) is performed to etch through the ESL 216a at the bottom of the trench(es) 232 to extend the trench(es) 232 through the ESL 216a and to the underlying bottom contact 228. Thus, the bottom contact 228 is exposed through the trench(es) 232 after the third etch operation. The third etch operation may be performed using the second etch tool and using a fluorine-based etchant such as a carbon fluoride-based (CFₓ such as CF₄) gas etchant. The dielectric masking layer 402 remains on the ILD layer 214d during the third etch operation to etch through the ESL 216a such that the dielectric masking layer 402 protects the ILD layer 214d from being etched, which reduces the likelihood of critical dimension reduction. Following exposure of the bottom contact 228 in the trench(es) 232, the dielectric masking layer 402 is removed from the ILD layer 214d.

As shown in FIG. 4F, the adhesion layer 234 may be deposited on the sidewalls and on the bottom surfaces of the trench(es) 232. The bottom surfaces of the trench(es) 232 correspond to the top surface of the bottom contact 228, and thus the adhesion layer 234 may be in physical contact with the top surface of the bottom contact 228. The adhesion layer 234 may also be deposited on the top surface of the ILD layer 214d between adjacent trenches 232 such that the adhesion layer 234 may be in physical contact with the top surface of the ILD layer 214d. In some implementations, a deposition tool is used to conformally deposit the adhesion layer 234 such that the adhesion layer 234 conforms to the profile of the trench(es) 232. In some implementations, a conformal CVD technique and/or an ALD technique is used to deposit the adhesion layer 234.

As shown in FIG. 4G, the bottom electrode layer 236 may be deposited on the adhesion layer 234. Thus, the bottom electrode layer 236 is deposited on the sidewalls and on the bottom surfaces (which correspond to the top surface of the bottom contact 228) of the trench(es) 232. The bottom electrode layer 236 may also be deposited on the top surface of the adhesion layer 234 between adjacent trenches 232. In some implementations, a deposition tool is used to conformally deposit the bottom electrode layer 236 such that the bottom electrode layer 236 conforms to the profile of the trench(es) 232. In some implementations, a conformal CVD technique and/or an ALD technique is used to deposit the bottom electrode layer 236.

As shown in FIG. 4H, the insulator layer 238 may be deposited on the bottom electrode layer 236. Thus, the insulator layer 238 is deposited on the sidewalls and on the bottom surfaces (which correspond to the top surface of the bottom contact 228) of the trench(es) 232. The insulator layer 238 may also be deposited on the top surface of the bottom electrode layer 236 between adjacent trenches 232. In some implementations, a deposition tool is used to conformally deposit the insulator layer 238 such that the insulator layer 238 conforms to the profile of the trench(es) 232. In some implementations, a conformal CVD technique and/or an ALD technique is used to deposit the insulator layer 238. The enlarged circular portions B and C illustrate the conformal deposition of the first type dielectric layers 240-1, 240-2 and 240-3 and the second type dielectric layers 242-1 and 242-2 of the insulator layer 238 on the sidewalls and the bottom surfaces of the trench(es) 232, and on the top surface of the bottom electrode layer 236 between adjacent trenches 232.

In some implementations, a plurality of ALD cycles are performed to deposit the insulator layer 238. As described in more detail in connection with FIGS. 5A-5C, performing an ALD cycle may include depositing, using a first material precursor, aluminum oxide (AlₓO_{y} such as Al₂O₃), and depositing, using a second material precursor, zirconium oxide (ZrOₓ such as ZrO₂) on the aluminum oxide. The first material precursor is oxidized with an alcohol oxidant to form the aluminum oxide, and the second material precursor is oxidized to form the zirconium oxide. The plurality of ALD cycles are performed to deposit alternating atomic layers of aluminum oxide and zirconium oxide to form an Al₂O₃/ZrO₂/Al₂O₃/ZrO₂/Al₂O₃ (AZAZA) dielectric layer stack, where the first type dielectric layers 240-1, 240-2, and 240-3 are each aluminum oxide layers and the second type dielectric layers 242-1 and 242-2 are each aluminum oxide layers. Alternatively, the plurality of ALD cycles are performed to deposit another combination and/or arrangement of alternating atomic layers of aluminum oxide and zirconium oxide in which at least one of the outer layers of the dielectric layer stack is an aluminum oxide layer. For example, the plurality of ALD cycles may be performed to deposit an Al₂O₃/ZrO₂/Al₂O₃ (AZA) dielectric layer stack, an Al₂O₃/ZrO₂/Al₂O₃/ZrO₂/Al₂O₃/ZrO₂/Al₂O₃ (AZAZAZA) dielectric layer stack, or an Al₂O₃/ZrO₂/Al₂O₃/ZrO₂ (AZAZ) dielectric layer stack, among other examples.

In another example, as shown in FIG. 4I, the enlarged circular portions B and C illustrate the conformal deposition of one first type dielectric layer 240, and one second type dielectric layer 242 on the first type dielectric layer 240 of the insulator layer 238. The first type dielectric layer 240 and the second type dielectric layer 242 are deposited on the sidewalls and the bottom surfaces of the trench(es) 232, and on the top surface of the bottom electrode layer 236 between adjacent trenches 232. In some implementations, the first type dielectric layer 240 is a layer of aluminum oxide (AlₓO_{y} such as Al₂O₃), and the second type dielectric layer is a layer of zirconium oxide (ZrOₓ such as ZrO₂), so that the insulator layer 238 is a dielectric layer stack that includes a layer of aluminum oxide and a layer of zirconium oxide.

As shown in FIG. 4J, the top electrode layer 244 may be deposited on the insulator layer 238. The top electrode layer 244 may be deposited such that the top electrode layer 244 fills the remaining areas of the trench(es) 232. The top electrode layer 244 may also be deposited on the top surface of the insulator layer 238 between adjacent trenches 232. In some implementations, a deposition tool is used to conformally deposit the top electrode layer 244 using a PVD technique, a CVD technique, an ALD technique, and/or another suitable deposition technique.

As shown in FIG. 4K, capping layers are formed above the trenches 232 of the trench capacitor structure 226. For example, the oxide capping layer 246 may be formed above and/or on the top electrode layer 244, the oxynitride capping layer 248 may be formed above and/or on the oxide capping layer 246, and/or the nitride capping layer 250 may be formed above and/or on the oxynitride capping layer 248, among other examples.

A deposition tool may be used to deposit the oxide capping layer 246, the oxynitride capping layer 248, and/or the nitride capping layer 250 using a PVD technique, an ALD technique, a CVD technique, an oxidation technique, and/or another suitable deposition technique. The oxide capping layer 246, the oxynitride capping layer 248, and/or the nitride capping layer 250 may be deposited in one or more deposition operations. In some implementations, a planarization tool may be used to perform a planarization operation (e.g., a CMP operation) to planarize the oxide capping layer 246, the oxynitride capping layer 248, and/or the nitride capping layer 250 after the oxide capping layer 246, the oxynitride capping layer 248, and/or the nitride capping layer 250 are deposited.

As shown in FIG. 4L, the capping layers (e.g., the oxide capping layer 246, the oxynitride capping layer 248, and/or the nitride capping layer 250) may be used to etch and define the top electrode layer 244 of the trench capacitor structure 226. In some implementations, a pattern in a photoresist layer is used to etch the oxide capping layer 246, the oxynitride capping layer 248, and/or the nitride capping layer 250 to form a hard mask over the top electrode layer 244. In these implementations, a deposition tool may be used to form the photoresist layer on the nitride capping layer 250. An exposure tool may be used to expose the photoresist layer to a radiation source to pattern the photoresist layer. A developer tool may be used to develop and remove portions of the photoresist layer to expose the pattern. An etch tool may be used to etch the oxide capping layer 246, the oxynitride capping layer 248, and/or the nitride capping layer 250 based on the pattern to define the hard mask layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). An etch tool may then be used to etch the top electrode layer 244 based on the hard mask layer (e.g., based on the pattern in the oxide capping layer 246, the oxynitride capping layer 248, and/or the nitride capping layer 250) to define the top electrode layer 244.

As shown in FIG. 4M, spacer layers 408 and 410 are formed above the capping layers (e.g., the oxide capping layer 246, the oxynitride capping layer 248, and/or the nitride capping layer 250). The spacer layers 408 and 410 extend along the ends of the capping layers (e.g., along the ends of the oxide capping layer 246, the ends of the oxynitride capping layer 248, and/or the ends of the nitride capping layer 250) and along the ends of the top electrode layer 244. Moreover, the spacer layers 408 and 410 are formed on the exposed portions of the insulator layer 238.

A deposition tool may be used to deposit the spacer layers 408 and/or 410 using a PVD technique, an ALD technique, a CVD technique, an oxidation technique, and/or another suitable deposition technique. The spacer layers 408 and/or 410 may be deposited in one or more deposition operations. In some implementations, a planarization tool may be used to perform a planarization operation (e.g., a CMP operation) to planarize the spacer layers 408 and/or 410 after the spacer layers 408 and/or 410 are deposited.

As shown in FIG. 4N, the spacer layers 408 and 410 are etched along with portions of the insulator layer 238, portions of the bottom electrode layer 236, and portions of the adhesion layer 234 to define the bottom electrode layer 236 of the MIM structure of the trench capacitor structure 226. The etch operation may be referred to as a CBM etch operation. In some implementations, the etch operation includes a dry etch operation (e.g., a plasma-based etch operation, a gas-based etch operation), a wet chemical etch operation, and/or another type of etch operation. Etching of the spacer layers 408 and 410 removes portions of the spacer layers 408 and 410 from the top of the nitride capping layer 250, resulting in formation of the sidewall spacers 252 and 254 on the ends of the oxide capping layer 246, the ends of the oxynitride capping layer 248, the ends of the nitride capping layer 250, and the ends of the top electrode layer 244. Moreover, etching of the spacer layers 408 and 410 results in the sidewall spacers 254 having rounded outer surfaces.

An etchant (e.g., a gas-based etchant, a plasma-based etchant) may be used to achieve an anisotropic etch of the spacer layers 408 and 410. The spacer layers 408 and 410 may be etched along with portions of the insulator layer 238, portions of the bottom electrode layer 236, and portions of the adhesion layer 234. The anisotropic etch primarily etches in the z-direction in the semiconductor device 200, enabling minimal lateral etching of the bottom electrode layer 236 and of the insulator layer 238 to be achieved.

As shown in FIG. 4O, additional material of the ILD layer 214d may be formed to encapsulate the trench capacitor structure 226. A deposition tool may be used to deposit the additional material of the ILD layer 214d using a PVD technique, an ALD technique, a CVD technique, an epitaxy technique, an oxidation technique, and/or another suitable deposition technique. The additional material of the ILD layer 214d may be deposited in one or more deposition operations. In some implementations, a planarization tool may be used to perform a planarization operation (e.g., a CMP operation) to planarize the ILD layer 214d after the additional material of the ILD layer 214d is deposited.

As shown in FIG. 4P, a recess 412 may be formed in the ILD layer 214d, through the capping layers 246-250, and to the top electrode layer 244 of the trench capacitor structure 226. Thus, the top electrode layer 244 may be exposed through the recess 412.

In some implementations, a pattern in a photoresist layer is used to etch the ILD layer 214d, the oxide capping layer 246, the oxynitride capping layer 248, and/or the nitride capping layer 250 to form the recess 412. In these implementations, a deposition tool may be used to form the photoresist layer on the ILD layer 214d. An exposure tool may be used to expose the photoresist layer to a radiation source to pattern the photoresist layer. A developer tool may be used to develop and remove portions of the photoresist layer to expose the pattern. An etch tool may be used to etch the ILD layer 214d, the oxide capping layer 246, the oxynitride capping layer 248, and/or the nitride capping layer 250 based on the pattern to form the recess 412. In some implementations, one or more etch operations are performed to etch the ILD layer 214d, the oxide capping layer 246, the oxynitride capping layer 248, and/or the nitride capping layer 250. In some implementations, the one or more etch operations may include a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 412 based on a pattern.

As shown in FIG. 4Q, the top contact 230 may be formed in the recess 412. A deposition tool may be used to deposit the material of the top contact 230 using a CVD technique, a PVD technique, an ALD technique, an electroplating technique, and/or another suitable deposition technique. The top contact 230 may be deposited in one or more deposition operations. In some implementations, a seed layer is first deposited, and the top contact 230 is deposited on the seed layer. In some implementations, a planarization tool is used to perform a planarization operation (e.g., a CMP operation) to planarize the top contact 230 after the top contact 230 is deposited.

As indicated above, FIGS. 4A-4Q are provided as an example. Other examples may differ from what is described with regard to FIGS. 4A-4Q.

FIGS. 5A-5C illustrate example implementations 500, 502, and 504 of the insulator layer 238 described herein. The example implementations 500, 502, and 504 illustrate example ALD techniques in which alternating first type dielectric layers 240-1, 240-2, and 240-3 and second type dielectric layers 242-1 and 242-2 are deposited on the bottom electrode layer 236 to form the Al₂O₃/ZrO₂/Al₂O₃/ZrO₂/Al₂O₃ (AZAZA) dielectric layer stack. A plurality of operations in the ALD technique are performed as a function of time.

A plurality of ALD cycles are performed to form the insulator layer 238. An ALD cycle in the example implementations 500, 502, and 504 includes the use of sequential gas-phase precursors (or reactants). The semiconductor device 200 is placed in a processing chamber of a deposition tool, and an oxygen-containing gas is pulsed in the ALD cycle to perform an oxygen treatment on the semiconductor device 200. The oxygen-containing gas may include tert-Butanol ((CH₃)₃COH)), isomers of tert-Butanol (e.g., 1-butanol (C₄H₉OH), isobutanol ((CH₃)₂CHCH₂OH), and butan-2-ol (CH₃CH(OH)CH₂CH₃)) and/or another alcohol oxidant. The duration of the pulse of the oxygen-containing gas may be included in a range of approximately 0.1 seconds to approximately 3 seconds. However, other values for the range are within the scope of the present disclosure.

The pulse of the oxygen-containing gas may be followed by a first pulse of a first metal material precursor, in which the first metal material precursor is provided to the processing chamber of the deposition tool. The first metal material precursor may include an aluminum gas-phase precursor for an aluminum oxide layer (e.g., dielectric layer 240-1, 240-2, or 240-3). Examples of aluminum precursors include trimethylaluminum (TMA) (C₃H₉Al), dimethylaluminum hydride (DMAH) ((CH₃)₂AlH), and dimethylethylamine alane (DMEAA) (AlH₃:N(CH₃)₂(CH₂CH₃)), among other examples. The duration of the first pulse of the first metal material precursor may be included in a range of approximately 0.1 seconds to approximately 3 seconds. However, other values for the range are within the scope of the present disclosure. The reaction between trimethylaluminum (TMA) and 1-butanol may include:

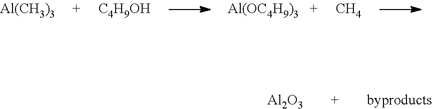

The byproducts may include hydrocarbons and water. The reaction between the first material precursor and the alcohol oxidant may be performed within a temperature range of approximately 300 degrees Celsius to approximately 400 degrees Celsius. If the temperature is greater than 400 degrees Celsius, the implant profile of a CMOS image sensor may be impacted, resulting in, for example, white pixel degradation. If the temperature in less than 300 degrees Celsius, the ability of the insulator layer 238 to fill in gaps in the trench(es) 232 may decrease due to lower temperatures not providing sufficient energy to cause molecules to decompose. However, other values for the range are within the scope of the present disclosure.

The use of an alcohol oxidant prevents oxidation of the underlying bottom electrode layer 236, so that an interlayer is not formed between the bottom electrode layer 236 and dielectric layer 240-1 of the insulator layer 238. If other types of oxidants (e.g., non-alcohol oxidants) are used to oxidize the first metal material precursor, the other types of oxidants may cause oxidation of the underlying bottom electrode layer 236, resulting in the formation of an interlayer, including an oxide of the bottom electrode layer 236, between the bottom electrode layer 236 and dielectric layer 240-1 of the insulator layer 238.

Since the oxygen dislocation energy of aluminum oxide (AlₓO_{y} such as Al₂O₃) (e.g., approximately 5 electron volts (eV)) is higher than the oxygen dislocation energy of zirconium oxide (ZrOₓ such as ZrO₂) (e.g., approximately 0.5 electron volts (eV)), when aluminum oxide is formed on the bottom electrode layer 236 as an outer dielectric layer 240-1 of the Al₂O₃/ZrO₂/Al₂O₃/ZrO₂/Al₂O₃ (AZAZA) dielectric layer stack, the likelihood of degradation of the dielectric layer 240-1 by diffusion of oxygen into the underlying bottom electrode layer 236 is reduced as compared to when a zirconium oxide layer is formed on the bottom electrode layer 236. As a result, the Al₂O₃/ZrO₂/Al₂O₃/ZrO₂/Al₂O₃ (AZAZA) dielectric layer stack is less susceptible to charge trapping than a ZrO₂/Al₂O₃/ZrO₂ (ZAZ) arrangement. Moreover, the lack of an interlayer in the trench capacitor structure 226 when the insulator layer 238 is an Al₂O₃/ZrO₂/Al₂O₃/ZrO₂/Al₂O₃ (AZAZA) dielectric layer stack results in increased capacitance as compared to a capacitor structure including a ZrO₂/Al₂O₃/ZrO₂ (ZAZ) dielectric layer stack and an interlayer between the ZrO₂/Al₂O₃/ZrO₂ (ZAZ) dielectric layer stack and a bottom electrode layer. The increase in capacitance is illustrated by the following formula for total capacitance (C_{Total}), where C_{Inter} is the capacitance of the interlayer and C_{Insul} is the capacitance of the insulator layer.

$$1 / {C}_{Total} = 1 / {C}_{Inter} + 1 / {C}_{Insul}$$

As can be understood, if the interlayer is not present, the capacitance of the interlayer does not reduce the total capacitance (C_{Total}).

Continuing with an ALD cycle in the example implementation 500, following deposition of an atomic layer of aluminum oxide (e.g., dielectric layer 240-1 or dielectric layer 240-2), the first metal material precursor is subsequently purged from the processing chamber, and another pulse of the oxygen-containing gas may be provided to the processing chamber. In this case, the oxygen-containing gas may include ozone (O₃), oxygen (O₂), water vapor (H₂O), and/or another oxygen-containing gas. The pulse of the oxygen-containing gas may be followed by a pulse of a second metal material precursor, in which the second metal material precursor is provided to the processing chamber of the deposition tool. The second metal material precursor may include a zirconium gas-phase precursor for a zirconium oxide layer (e.g., dielectric layer 242-1 or 242-2). Examples of zirconium precursors include zirconium(IV) tert-butoxide (Zr[OC(CH₃)₃]₄), zirconium(IV) iodide (ZrI₄), zirconium(IV) chloride (ZrCl₄), and tetrakis(dimethylamido)zirconium(IV) (Zr(NMe₂)₄), among other examples. The duration of the pulse of the second metal material precursor may be included in a range of approximately 0.1 seconds to approximately 3 seconds. However, other values for the range are within the scope of the present disclosure.

The first pulse of the first metal material precursor may react with the oxygen-containing gas (e.g., alcohol-based oxidant) to form a first aluminum oxide layer (e.g., dielectric layer 240-1) of the insulator layer 238. The first aluminum oxide layer includes an oxygenized metal material (e.g., a metal oxide material) that includes the metal (e.g., aluminum) of the first metal material precursor. The first pulse of the second metal material precursor may react with the oxygen-containing gas (e.g., non-alcohol-based oxidant) to form a first zirconium oxide layer (e.g., dielectric layer 242-1) of the insulator layer 238 on the first aluminum oxide layer. The first zirconium oxide layer includes an oxygenized metal material (e.g., a metal oxide material) that includes the metal (e.g., zirconium) of the second metal material precursor.

Additional ALD cycles may be performed to form repeating alternate atomic layers (e.g., aluminum oxide layers (remaining first type dielectric layers 240-2 and 240-3) and a zirconium oxide layer (remaining second type dielectric layer 242-2)) on the first aluminum oxide layer and the first zirconium oxide layer as shown in FIGS. 5A-5C.

In some implementations, the plurality of ALD cycles are performed to deposit alternating atomic layers of aluminum oxide and zirconium oxide at the same or different deposition rates. In particular, atomic layers of a first high-k metal oxide (e.g., aluminum oxide) can be deposited at approximately the same rate as, a greater rate than, or a lesser rate than atomic layers of a second high-k metal oxide (e.g., zirconium oxide) in an ALD cycle.

The time duration of each ALD cycle may be included in a range of approximately 3 seconds to approximately 6 seconds. However, other values for the range are within the scope of the present disclosure. In some implementations, the amount of time for the reaction of pulses of the first metal material precursor with the oxygen-containing gas and/or the amount of first metal material precursor is controlled to increase or decrease a deposited thickness of the aluminum oxide layers. Similarly, the amount of time for the reaction of pulses of the second metal material precursor with the oxygen-containing gas and/or the amount of second metal material precursor is controlled to increase or decrease a deposited thickness of the zirconium oxide layers.

In some implementations, one or more ALD cycles may each include a greater quantity of pulses of the second metal material precursor than the quantity of pulses of the first metal material precursor to achieve a higher deposited thickness of a second metal oxide (e.g., zirconium oxide) in the insulator layer 238. For example, an ALD cycle may include 3 pulses of zirconium and 1 pulse of aluminum to achieve a thickness ratio of a thickness of a zirconium oxide layer to a thickness of an aluminum oxide layer that is approximately 3:1.

Alternatively, one or more ALD cycles may each include a greater quantity of pulses of the first metal material precursor than the quantity of pulses of the second metal material precursor to achieve a higher deposited thickness of a first metal oxide (e.g., aluminum oxide) in the insulator layer 238. In some implementations, one or more ALD cycles may include the same quantity of pulses for the first metal precursor and the second metal precursor to achieve approximately a same deposited thickness of the first metal oxide and the second metal oxide.

In some implementations, a combined deposited thickness of the zirconium oxide layers in the z-direction can be greater than a combined deposited thickness of the aluminum oxide layers in the z-direction. The dielectric constant of zirconium oxide is greater than the dielectric constant of aluminum oxide. Thus, the combined thickness of the zirconium oxide layers being greater than the combined thickness of the aluminum oxide layers means that the overall composition of the insulator layer 238 includes a greater amount of zirconium oxide than aluminum oxide, which enables a higher overall dielectric constant to be achieved for the insulator layer 238, which enables a greater capacitance to be achieved for the capacitor structure 226 in which the insulator layer 238 is included.

Alternatively, a combined deposited thickness of the zirconium oxide layers in the z-direction can be less than a combined deposited thickness of the aluminum oxide layers in the z-direction, or approximately equal to a combined deposited thickness of the aluminum oxide layers in the z-direction.

The thicknesses of individual zirconium oxide layers and aluminum oxide layers in the z-direction can similarly be increased or decreased by varying reaction time and/or precursor amounts during a given ALD cycle.

Referring to the example implementation 500 in FIG. 5A, a thickness of each of the first type dielectric layers 240-1, 240-2, and 240-3 (e.g., aluminum oxide layers) in the z-direction is less than a thickness of each of the second type dielectric layers 242-1 and 242-2 (e.g., zirconium oxide layers) in the z-direction. For example, thicknesses of the first type dielectric layers 240-1, 240-2, and 240-3 (e.g., aluminum oxide layers) in the z-direction may be approximately the same as each other, and may be approximately 5 angstroms to approximately 10 angstroms. However, other values and ranges are within the scope of the present disclosure.

Thicknesses of the second type dielectric layers 242-1 and 242-2 (e.g., zirconium oxide layers) in the z-direction may be approximately the same as each other, and may be approximately 16 angstroms to approximately 20 angstroms. However, other values and ranges are within the scope of the present disclosure.

In an example, the ratio of thicknesses of the second type dielectric layers 242-1 and 242-2 (e.g., zirconium oxide layers) in the z-direction to the thicknesses of the first type dielectric layers 240-1, 240-2, and 240-3 (e.g., aluminum oxide layers) in the z-direction is approximately 9:4. To achieve this example ratio, an ALD cycle may include 9 pulses of zirconium and 4 pulses of aluminum to achieve a thickness ratio of a thickness of a zirconium oxide layer to a thickness of an aluminum oxide layer that is approximately 9:4. However, other ratios are within the scope of the present disclosure.

Referring to the example implementation 502 in FIG. 5B, a thickness of each of the first type dielectric layers 240-1, 240-2, and 240-3 (e.g., aluminum oxide layers) in the z-direction is less than a thickness of each of the second type dielectric layers 242-1 and 242-2 (e.g., zirconium oxide layers) in the z-direction. For example, a thickness of the dielectric layer 240-1 in the z-direction may be approximately 10 angstroms to approximately 14 angstroms, and thicknesses of the dielectric layers 240-2 and 240-3 in the z-direction each may be approximately 5 angstroms to approximately 7 angstroms. However, other values and ranges are within the scope of the present disclosure. In an example, a ratio of the thickness of the dielectric layer 240-1 in the z-direction to the ratio of the thicknesses of the dielectric layers 240-2 and 240-3 in the z-direction is approximately 2:1. However, other ratios are within the scope of the present disclosure.

Thicknesses of the second type dielectric layers 242-1 and 242-2 (e.g., zirconium oxide layers) in the z-direction may be approximately the same as each other, and may be approximately 16 angstroms to approximately 20 angstroms. In this case, the ratio of thicknesses of the second type dielectric layers 242-1 and 242-2 (e.g., zirconium oxide layers) in the z-direction to the thickness of the first type dielectric layer 240-1 (e.g., aluminum oxide layer) in the z-direction is 3:2, and the ratio of thicknesses of the second type dielectric layers 242-1 and 242-2 (e.g., zirconium oxide layers) in the z-direction to the thicknesses of the first type dielectric layers 240-2 and 240-3 (e.g., aluminum oxide layers) in the z-direction is 3:1. However, other ratios are within the scope of the present disclosure. To achieve the example ratios, an ALD cycle including the deposition of the first type dielectric layer 240-1 may include 3 pulses of zirconium and 2 pulses of aluminum to achieve a thickness ratio of a thickness of a zirconium oxide layer to a thickness of an aluminum oxide layer that is approximately 3:2, and an ALD cycle including the deposition of the first type dielectric layers 240-2 or 240-3 may include 3 pulses of zirconium and 1 pulse of aluminum to achieve a thickness ratio of a thickness of a zirconium oxide layer to a thickness of an aluminum oxide layer that is approximately 3:1.

Referring to the example implementation 504 in FIG. 5C, a thickness of each of the first type dielectric layers 240-1, 240-2, and 240-3 (e.g., aluminum oxide layers) in the z-direction is less than a thickness of each of the second type dielectric layers 242-1 and 242-2 (e.g., zirconium oxide layers) in the z-direction. For example, a thickness of the dielectric layer 240-1 in the z-direction may be approximately 15 angstroms to approximately 17 angstroms, and thicknesses of the dielectric layers 240-2 and 240-3 in the z-direction each may be approximately 3 angstroms to approximately 5 angstroms. In an example, a ratio of the thickness of the dielectric layer 240-1 in the z-direction to the ratio of the thicknesses of the dielectric layers 240-2 and 240-3 in the z-direction is approximately 4:1. However, other ratios are within the scope of the present disclosure.

Thicknesses of the second type dielectric layers 242-1 and 242-2 (e.g., zirconium oxide layers) in the z-direction may be approximately the same as each other, and may be approximately 16 angstroms to approximately 20 angstroms. The thicknesses of each of the second type dielectric layers 242-1 and 242-2 may be greater than the thicknesses of each of the first type dielectric layers 240-1, 240-2, and 240-3. In an example, the ratio of thicknesses of the second type dielectric layers 242-1 and 242-2 (e.g., zirconium oxide layers) in the z-direction to the thickness of the first type dielectric layer 240-1 (e.g., aluminum oxide layer) in the z-direction is 9:8, and the ratio of thicknesses of the second type dielectric layers 242-1 and 242-2 (e.g., zirconium oxide layers) in the z-direction to the thicknesses of the first type dielectric layers 240-2 and 240-3 (e.g., aluminum oxide layers) in the z-direction is 9:2. However, other ratios are within the scope of the present disclosure. To achieve the example ratios, an ALD cycle including the deposition of the first type dielectric layer 240-1 may include 9 pulses of zirconium and 8 pulses of aluminum to achieve a thickness ratio of a thickness of a zirconium oxide layer to a thickness of an aluminum oxide layer that is approximately 9:8, and an ALD cycle including the deposition of the first type dielectric layers 240-2 or 240-3 may include 9 pulses of zirconium and 2 pulse of aluminum to achieve a thickness ratio of a thickness of a zirconium oxide layer to a thickness of an aluminum oxide layer that is approximately 9:2.

In some implementations, a relatively thicker first aluminum oxide layer (e.g., dielectric layer 240-1) directly on the bottom electrode layer 236 reduces lag in an image sensor device in which the trench capacitor structure 226 including the insulator layer 238 is included. The lag reduction (which may refer to a reduction in lag in discharging the trench capacitor structure 226) is due to the increased thickness providing an increased ability to block downward oxygen diffusion (e.g., tunneling) from an adjacent zirconium oxide layer (e.g., dielectric layer 242-1) into the bottom electrode layer 236. For example, referring to the example implementations 500-504 in FIGS. 5A-5C, as the thickness of the dielectric layer 240-1 increases in the z-direction (e.g., from 8 angstroms to 12 angstroms to 16 angstroms), lag may progressively decrease for given devices including trench capacitor structures 226 with the insulator layers 238 of the example implementations 500-504.

In some implementations, the ALD cycles are repeated until the insulating layer 238 has a thickness in the z-direction of approximately 50 angstroms to approximately 80 angstroms. However, other values for the ranges are within the scope of the present disclosure. A thickness in the z-direction of the insulating layer 238 below approximately 50 angstroms may result in unwanted current leakage, and a thickness in the z-direction of the insulating layer 238 above approximately 80 angstroms may leave insufficient space for formation of the top electrode layer 244, resulting in unwanted larger resistance.

As indicated above, FIGS. 5A-5C are provided as examples. Other examples may differ from what is described with regard to FIGS. 5A-5C.

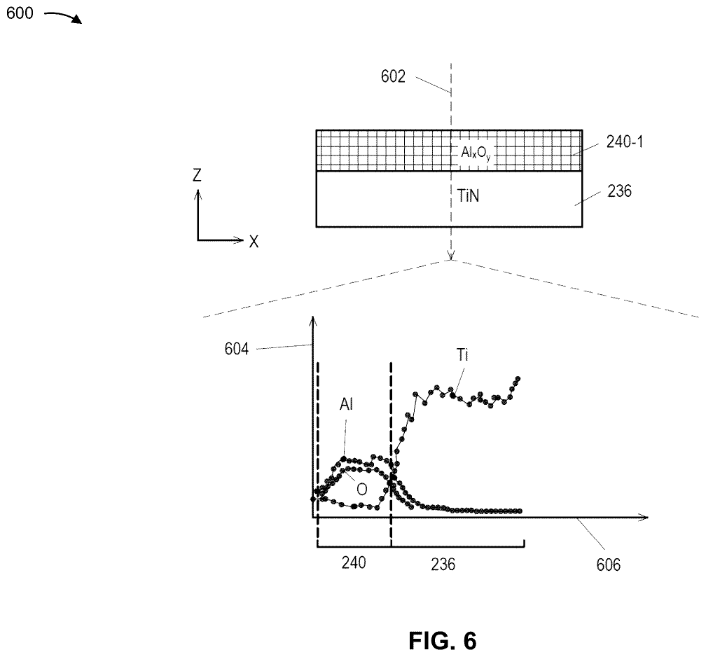

FIG. 6 illustrates an elemental composition 600 of the dielectric layer 240-1 and the bottom electrode layer 236 along a depth profile 602 of the dielectric layer 240-1 and the bottom electrode layer 236. The elemental composition 600 is illustrated as an atomic percentage 604 of one or more elements in the dielectric layer 240-1 and in the bottom electrode layer 236, as a function of depth 606 in the dielectric layer 240-1 and in the bottom electrode layer 236. In particular, the atomic percentage 604 of the one or more elements is illustrated from a top surface of the dielectric layer 240-1 to a bottom surface of the bottom electrode layer 236. As used herein, “concentration” refers to a quantity of a given substance with respect to volume (e.g., atoms per cm³).

As shown in the depth profile 602 in FIG. 6, the dielectric layer 240-1 may include aluminum oxide (AlₓO_{y} (e.g., Al₂O₃)) and the bottom electrode layer 236 may include titanium nitride (TiN). In the dielectric layer 240-1, the atomic percentage 604 (or concentration) of aluminum (Al) and the atomic percentage 604 (or concentration) of oxygen (O) each follow a general parabolic curve, such that the concentrations of aluminum (Al) and oxygen (O) increase, peak, and then decrease along a depth 606 of the dielectric layer 240-1 so that the concentrations of aluminum (Al) and oxygen (O) at or near a middle portion of the dielectric layer 240-1 along a z-direction are greater than at or near top and bottom surfaces of the dielectric layer 240-1. In the bottom electrode layer 236, the atomic percentage 604 (or concentration) of aluminum (Al) and the atomic percentage 604 (or concentration) of oxygen (O) each sharply decrease to about zero along a depth 606 of the bottom electrode layer 236. As can be understood from the depth profile 602, with the exception of a portion at or near an interface between the dielectric layer 240-1 and the bottom electrode layer 236 (e.g., near the top surface of the bottom electrode 236 and the bottom surface of the dielectric layer 240-1), the bottom electrode layer 236 lacks aluminum (Al) and oxygen (O).

Since the curves for aluminum (Al) and oxygen (O) have approximately the same parabolic shape and have segments that are approximately parallel to each other along the depth 606 through the dielectric layer 240-1 and bottom electrode layer 236, in some implementations, the ratio of the atomic percentage 604 (or concentration) of aluminum (Al) to the atomic percentage 604 (or concentration) of oxygen (O) is substantially uniform (e.g., is unchanged) along the depth 606 through the dielectric layer 240-1 and bottom electrode layer 236.

In the dielectric layer 240-1, the atomic percentage 604 (or concentration) of titanium nitride (TiN) is about zero along a depth 606 of the dielectric layer 240-1. As can be understood from the depth profile 602, with the exception of a portion at or near an interface between the dielectric layer 240-1 and the bottom electrode layer 236 (e.g., near the top surface of the bottom electrode 236 and the bottom surface of the dielectric layer 240-1), the dielectric layer 240-1 lacks titanium nitride (TiN). In the bottom electrode layer 236, the atomic percentage 604 (or concentration) of titanium nitride (TiN) increases, plateaus, then increases again along a depth 606 of the bottom electrode layer 236. As can be understood from the depth profile 602, the concentration of titanium nitride (TiN) increases deeper into the bottom electrode layer 236 and away from the dielectric layer 240-1 in the z-direction. The concentration of titanium nitride (TiN) is greater at or near a middle portion of the bottom electrode layer 236 along a z-direction than at or near a top surface of the bottom electrode layer 236, and greatest at or near a bottom surface of the bottom electrode layer 236.

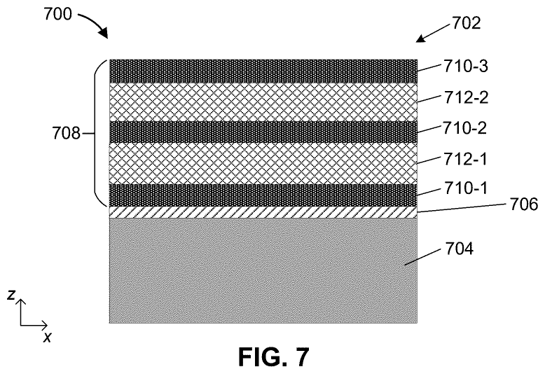

FIG. 7 is a diagram of an example implementation 700 of a portion of a trench capacitor structure 702. Referring to the example implementation 700 in FIG. 7, a bottom electrode layer 704 of the trench capacitor structure 702 is the same as or similar to the bottom electrode layer 236 of the trench capacitor structure 226. For example, the bottom electrode layer 704 includes one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. An interlayer 706 is formed on the bottom electrode layer 704, and an insulator layer 708 is formed on the interlayer 706. Unlike the trench capacitor structure 226, which lacks an interlayer between the bottom electrode layer 236 and the insulator layer 238, the trench capacitor structure 702 includes the interlayer 706 between the bottom electrode layer 704 and the insulator layer 708. The interlayer 706 is formed as a result of the reactants used in the ALD process for forming the insulator layer 708.

The insulator layer 708 is an insulator layer stack including a plurality of first type dielectric layers 710-1, 710-2, and 710-3 and second type dielectric layers 712-1 and 712-2. Like the first type dielectric layers 240-1, 240-2, and 240-3 and second type dielectric layers 242-1 and 242-2 of the trench capacitor structure 226, the first type dielectric layers 710-1, 710-2, and 710-3 are alternately arranged with the second type dielectric layers 712-1 and 712-2. In some implementations, the first type dielectric layers 710-1, 710-2, and 710-3 are each a layer of aluminum oxide (AlₓO_{y} such as Al₂O₃) and the second type dielectric layers 712-1 and 712-2 are each a layer of zirconium oxide (ZrOₓ such as ZrO₂) so that the insulator layer 708 is an Al₂O₃/ZrO₂/Al₂O₃/ZrO₂/Al₂O₃ (AZAZA) dielectric layer stack. Like the first type dielectric layers 240-1, 240-2, and 240-3 and second type dielectric layers 242-1 and 242-2 of the trench capacitor structure 226, the first type dielectric layers 710-1, 710-2, and 710-3 and the second type dielectric layers 712-1 and 712-2 may be part of a DTC structure. In some implementations, the dielectric layer 240-1 is directly formed on the bottom electrode layer 236 and adjacent ones of the first type dielectric layers 240-1, 240-2, and 240-3, and the second type dielectric layers 242-1 and 242-2 are directly formed on each other. In some implementations, a thickness of each of the first type dielectric layers 710-1, 710-2, and 710-3 (e.g., aluminum oxide layers) in the z-direction is less than a thickness of each of the second type dielectric layers 712-1 and 712-2 (e.g., zirconium oxide layers) in the z-direction.

A plurality of ALD cycles are performed to form the insulator layer 708. An ALD cycle in the example implementation 700 includes the use of sequential gas-phase precursors (or reactants). A semiconductor device in which the trench capacitor structure 702 is being formed is placed in a processing chamber of a deposition tool, and an oxygen-containing gas is pulsed in the ALD cycle to perform an oxygen treatment on the semiconductor device. The oxygen-containing gas may include ozone (O₃), oxygen (O₂), water vapor (H₂O), and/or another oxygen-containing gas. The duration of the pulse of the oxygen-containing gas may be included in a range of approximately 0.1 seconds to approximately 3 seconds. However, other values for the range are within the scope of the present disclosure.

The pulse of the oxygen-containing gas may be followed by a first pulse of a first metal material precursor, in which the first metal material precursor is provided to the processing chamber of the deposition tool. The first metal material precursor may include an aluminum gas-phase precursor for an aluminum oxide layer (e.g., dielectric layer 710-1, 710-2, or 710-3). Examples of aluminum precursors include trimethylaluminum (TMA) (C₃H₉Al), dimethylaluminum hydride (DMAH) ((CH₃)₂AlH), and dimethylethylamine alane (DMEAA) (AlH₃:N(CH₃)₂(CH₂CH₃)), among other examples. The duration of the first pulse of the first metal material precursor may be included in a range of approximately 0.1 seconds to approximately 3 seconds. However, other values for the range are within the scope of the present disclosure. The reaction between trimethylaluminum (TMA) and ozone (O₃) may include:

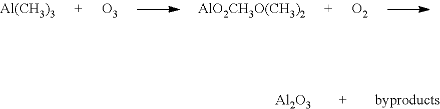

The byproducts may include hydrocarbons and water. The reaction between the first material precursor and the alcohol oxidant may be performed within a temperature range of approximately 170 degrees Celsius to approximately 210 degrees Celsius. The use of ozone (O₃) or another non-alcohol-based oxidant results in some oxidation of the underlying bottom electrode layer 704, so that an interlayer 706 including an oxidized material of the bottom electrode layer 704 (e.g., titanium oxide (TiOₓ such as TiO₂) and/or titanium oxynitride (TiOₓN_{y})) is formed between the bottom electrode layer 704 and dielectric layer 710-1 of the insulator layer 708.

Continuing with an ALD cycle in the example implementation 700, following deposition of an atomic layer of aluminum oxide (e.g., dielectric layer 710-1 or dielectric layer 710-2), the first metal material precursor is subsequently purged from the processing chamber, and another pulse of the oxygen-containing gas may be provided to the processing chamber. The pulse of the oxygen-containing gas may be followed by a pulse of a second metal material precursor, in which the second metal material precursor is provided to the processing chamber of the deposition tool. The second metal material precursor may include a zirconium gas-phase precursor for a zirconium oxide layer (e.g., dielectric layer 712-1 or 712-2). Examples of zirconium precursors include zirconium(IV) tert-butoxide (Zr[OC(CH₃)₃]₄), zirconium(IV) iodide (ZrI₄), zirconium(IV) chloride (ZrCl₄), and tetrakis(dimethylamido)zirconium(IV) (Zr(NMe₂)₄), among other examples. The duration of the pulse of the second metal material precursor may be included in a range of approximately 0.1 seconds to approximately 3 seconds. However, other values for the range are within the scope of the present disclosure.

Additional ALD cycles may be performed to form repeating alternating atomic layers (e.g., aluminum oxide layers (remaining first type dielectric layers 710-2 and 710-3) and a zirconium oxide layer (remaining second type dielectric layer 712-2)) on the first aluminum oxide layer and the first zirconium oxide layer as shown in FIG. 7.

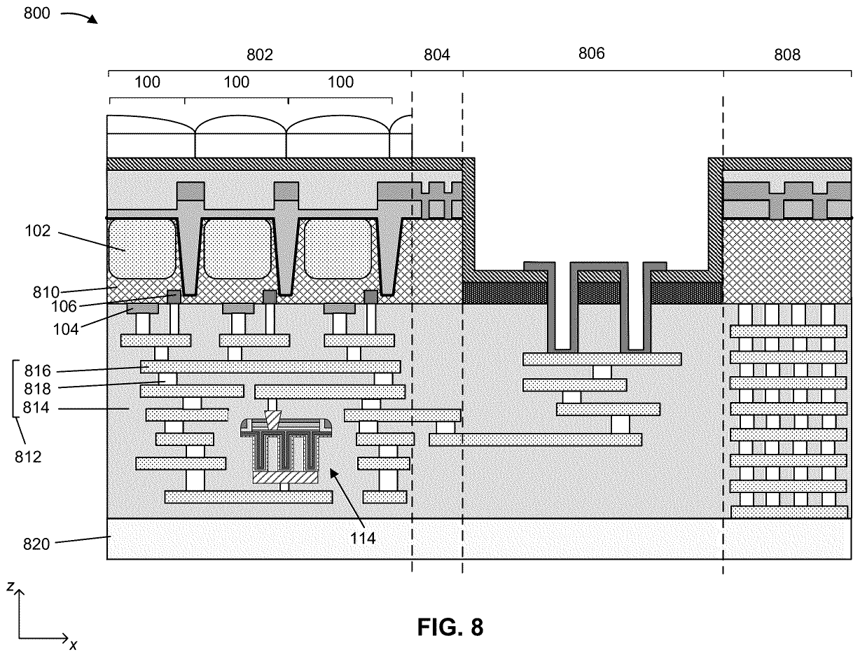

FIG. 8 is a diagram of an example semiconductor device 800 described herein. The semiconductor device 800 may include an example of a three-dimensional image sensor (e.g., a 3D CMOS image sensor). The semiconductor device 800 may be configured to be deployed in various implementations, such as digital cameras, video recorders, night-vision cameras, automotive sensors and cameras, and/or other types of light-sensing implementations.

As shown in FIG. 8, the semiconductor device 800 may include a pixel sensor array 802. The semiconductor device 800 may further include a black level correction (BLC) region 804, a bonding pad region 806, and/or a seal ring region 808, among other examples. The pixel sensor array 802 may include a plurality of pixel sensors 100 arranged in an array. The pixel sensors 100 may be configured to sense incident light and convert photons of the incident light to a photocurrent. The pixel sensors 100 may be included in a device layer 810 of the semiconductor device 800. The pixel sensors 100 may each include one or more photodiodes 102 that are configured to generate a photocurrent based on photons of incident light. The pixel sensors 100 may further include a floating diffusion node 106 in the device layer 810 that is configured to temporarily store the photocurrent generated by an associated pixel sensor 100, and may each include a transfer gate 104 that is configured to control the flow of photocurrent from a photodiode 102 to a floating diffusion node 106. The pixel sensors 100 may be formed by one or more semiconductor processing tools using various semiconductor processing techniques, such as photolithography, etching, deposition, CMP, and/or ion implantation, among other examples.

The BLC region 804 includes a metal shielding layer over a portion of the device layer 810 so that a baseline measurement of current in the device layer 810 in the BLC region 804 can be performed to determine the dark current (e.g., the current in the device layer 810 that is generated from sources other than incident light, such as heat) of the pixel sensor array 802, so that the black level of the pixel sensor array 802 can be adjusted to compensate for the dark current. The bonding pad region 806 may include one or more conductive bonding pads (or e-pads) and/or metallization layers through which electrical connections between the semiconductor device 800 and outside devices and/or external packaging may be established. The seal ring region 808 may include an arrangement of metallization structures and interconnect structures to provide structural rigidity for the semiconductor device 800 and to protect the semiconductor device 800 from ingress of humidity and other contaminants.

As further shown in FIG. 8, the semiconductor device 800 may include an interconnect layer 812 under the device layer 810. The interconnect layer 812 may include a dielectric region 814 that includes one or more dielectric layers (e.g., ILD layers, intermetal dielectric (IMD) layers, ESLs) and an arrangement of metallization structures 816 and interconnect structures 818 in the dielectric region 814. A passivation layer 820 may be included under the interconnect layer 812.

As further shown in FIG. 8, one or more overflow capacitors 114 may be included in the interconnect layer 812. The overflow capacitor(s) 114 may be structurally implemented as the trench capacitor structure 226 illustrated and described herein. An overflow capacitor 114 may be electrically coupled to a floating diffusion node 106 of a pixel sensor 100 and may be configured to store overflow photocurrent from the floating diffusion node 106.

As indicated above, FIG. 8 is provided as an example. Other examples may differ from what is described with regard to FIG. 8.

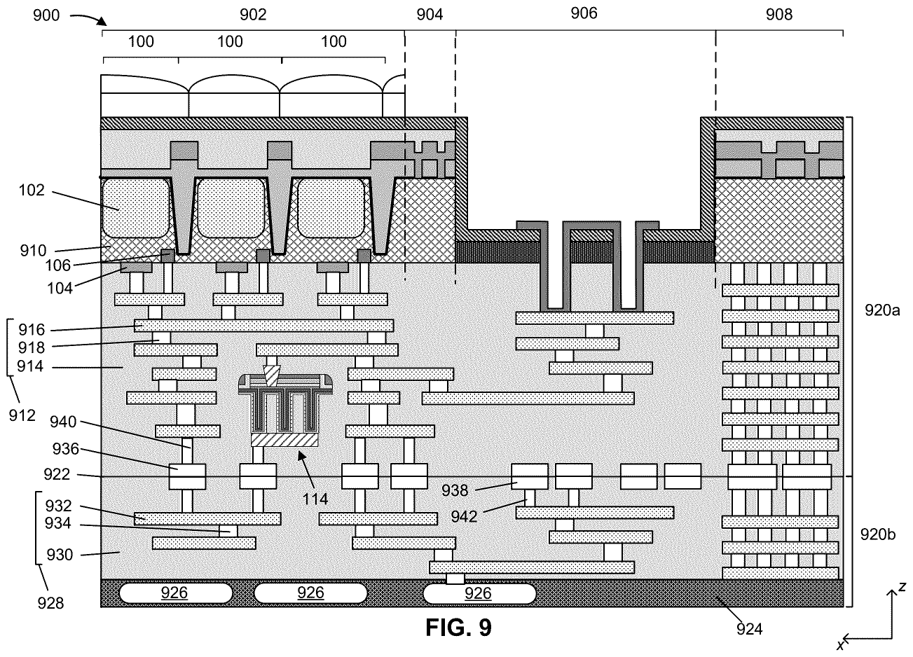

FIG. 9 is a diagram of an example semiconductor device 900 described herein. The semiconductor device 900 may include an example of a three-dimensional image sensor (e.g., a 3D CMOS image sensor). The semiconductor device 900 may be configured to be deployed in various implementations, such as digital cameras, video recorders, night-vision cameras, automotive sensors and cameras, and/or other types of light-sensing implementations.

As shown in FIG. 9, the semiconductor device 900 includes a similar combination of structures and/or layers as the semiconductor device 800. For example, the semiconductor device 900 may include elements 902-918, which are similar to the elements 802-818 of the semiconductor device 800.

However, the semiconductor device 900 includes a plurality of semiconductor dies, including a first semiconductor die 920a and a second semiconductor die 920b. The first semiconductor die 920a and the second semiconductor die 920b may be directly bonded together at a bonding interface 922 such that the first semiconductor die 920a and the second semiconductor die 920b are stacked and vertically arranged in a z-direction in the semiconductor device 900. The first semiconductor die 920a may be referred to as an image sensor die and may include the pixel sensor array 902 (including the pixel sensors 100), the BLC region 904, and the bonding pad region 906. The first semiconductor die 920a may also include the photodiodes 102, the transfer gates 104, the floating diffusion nodes 106, the device layer 910, and the interconnect layer 912 (including the dielectric region 914, the metallization structures 916 and the interconnect structures 918). In the example in FIG. 9, the overflow capacitor(s) 114 are included in the interconnect layer 912 of the first semiconductor die 920a. The seal ring region 908 may extend through both the first semiconductor die 920a and the second semiconductor die 920b.

As further shown in FIG. 9, the second semiconductor die 920b of the semiconductor device 900 may include a device layer 924, one or more integrated circuit devices 926 included in the device layer 924, and an interconnect layer 928 above the device layer 924. The interconnect layer 928 may include a dielectric region 930 that includes one or more dielectric layers (e.g., ILD layers, ESLs) and an arrangement of metallization structures 932 and interconnect structures 934 in the dielectric region 930 of the interconnect layer 928 of the second semiconductor die 920b.

The first semiconductor die 920a and the second semiconductor die 920b may be bonded at the bonding interface 922 by dielectric-to-dielectric bonds between the dielectric region 914 of the first semiconductor die 920a and the dielectric region 930 of the second semiconductor die 920b. Moreover, the first semiconductor die 920a and the second semiconductor die 920b may be bonded at the bonding interface 922 by metal-to-metal bonds between bonding pads 936 included in the interconnect layer 912 of the first semiconductor die 920a and bonding pads 938 included in the interconnect layer 928 of the second semiconductor die 920b. The bonding pads 936 may be electrically connected to the metallization structures 916 and the interconnect structures 918 in the interconnect layer 912 by bonding vias 940, and the bonding pads 938 may be electrically connected to the metallization structures 932 and the interconnect structures 934 in the interconnect layer 928 by bonding vias 942.

As indicated above, FIG. 9 is provided as an example. Other examples may differ from what is described with regard to FIG. 9.

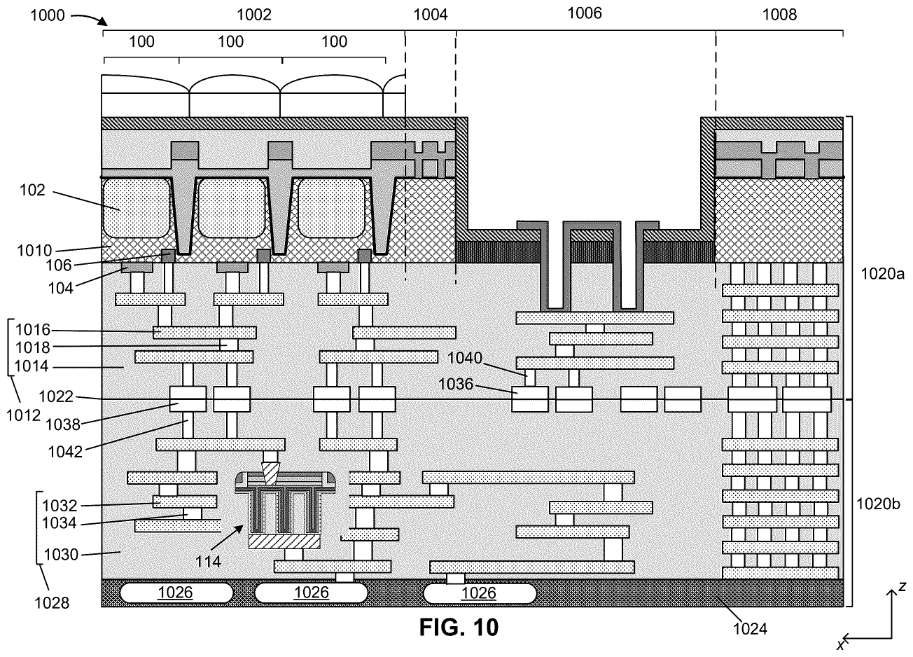

FIG. 10 is a diagram of an example semiconductor device 1000 described herein. The semiconductor device 1000 may include an example of a three-dimensional image sensor (e.g., a 3D CMOS image sensor). The semiconductor device 1000 may be configured to be deployed in various implementations, such as digital cameras, video recorders, night-vision cameras, automotive sensors and cameras, and/or other types of light-sensing implementations.

As shown in FIG. 10, the semiconductor device 1000 includes a similar combination of structures and/or layers as the semiconductor device 900. For example, the semiconductor device 1000 may include elements 1002-1042, which are similar to the elements 902-942 of the semiconductor device 900. The semiconductor device 900 may also include pixel sensors 100, photodiodes 102, transfer gates 104, floating diffusion nodes 106, and one or more overflow capacitors 114.

However, in the semiconductor device 1000, the one or more overflow capacitors 114 are included in the second semiconductor die 1020b (e.g., an application-specific integrated circuit (ASIC) die) as opposed to (or in addition to) being included in the first semiconductor die 1020a (e.g., the sensor die). Including the one or more overflow capacitors 114 on the second semiconductor die 1020b as opposed to the first semiconductor die 1020a enables a greater amount of the area in the first semiconductor die 1020a to be used for the photodiodes 102 (which provides increased full well capacity for the photodiodes 102) and/or for control circuitry of the pixel sensors 100 (e.g., for the transfer gates 104, the reset gates 108, the overflow gates 112), which may increase the performance of the semiconductor device 1000.

As indicated above, FIG. 10 is provided as an example. Other examples may differ from what is described with regard to FIG. 10.

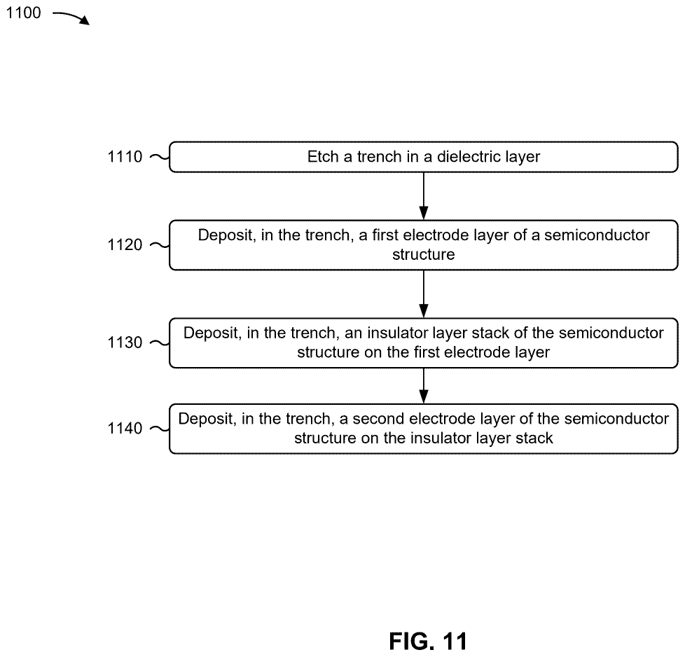

FIG. 11 is a flowchart of an example process 1100 associated with forming a semiconductor device. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include etching a trench in a dielectric layer (block 1110). For example, one or more semiconductor processing tools may be used to etch a trench (e.g., trench 232) in a dielectric layer (e.g., ILD layer 214 and/or ESL 216), as described herein.

As further shown in FIG. 11, process 1100 may include depositing, in the trench, a first electrode layer of a capacitor structure (block 1120). For example, one or more semiconductor processing tools may be used to deposit, in the trench, a first electrode layer (e.g., bottom electrode layer 236) of a capacitor structure (e.g., trench capacitor structure 226), as described herein.

As further shown in FIG. 11, process 1100 may include depositing, in the trench, an insulator layer stack of the capacitor structure on the first electrode layer (block 1130). For example, one or more semiconductor processing tools may be used to deposit, in the trench, an insulator layer stack (e.g., insulator layer 238) of the capacitor structure on the first electrode layer, as described herein. The insulator layer stack may include a first metal oxide layer (e.g., a first type dielectric layer 240) containing a first metal constituent (e.g., aluminum), and a second metal oxide layer (e.g., a second type dielectric layer 242) containing a second metal constituent (e.g., zirconium) that is different from the first metal constituent. The first metal oxide layer has a dielectric constant (e.g., approximately 3 to approximately 10.1 for aluminum oxide) that is lower than a dielectric constant of the second metal oxide layer (e.g., approximately 20 to 25 for zirconium oxide). The first metal constituent and the second metal constituent are different from a third metal constituent (e.g., titanium) of the first electrode layer (which may include titanium nitride (TiN). The first metal oxide layer may be closer to the first electrode layer than the second metal oxide layer (e.g., the first metal oxide layer may be on or directly adjacent to the first electrode layer). An interface between the first metal oxide layer and the first electrode layer is free of the second metal constituent (e.g., there are no intervening second metal oxide layers between the first metal oxide layer and the first electrode layer).

As further shown in FIG. 11, process 1100 may include depositing, in the trench, a second electrode layer of the capacitor structure on the insulator layer stack (block 1140). For example, one or more semiconductor processing tools may be used to deposit, in the trench, a second electrode layer (e.g., top electrode layer 244) of the capacitor structure on the insulator layer stack, as described herein.

Process 1100 may include additional implementations, such as any single implementation or any combination of implementations described below and/or in connection with one or more other processes described elsewhere herein.

In a first implementation, the insulator layer stack includes a plurality of first metal oxide layers (e.g., first type dielectric layers 240-1, 240-2 and 240-3) and a plurality of second metal oxide layers (e.g., second type dielectric layers 242-1 and 242-2). In some implementations, a first metal oxide layer (e.g., dielectric layer 240-1) of the plurality of first metal oxide layers is an outer layer of the insulator layer stack and is adjacent to the first electrode layer.

In a second implementation, alone or in combination with the first implementation, forming the insulator layer stack includes performing a plurality of ALD cycles to deposit the insulator layer stack, where performing an ALD cycle, of the plurality of ALD cycles, includes depositing, using a first material precursor and an alcohol oxidant, the first metal oxide layer on the first electrode layer, and depositing, using a second material precursor, a second metal oxide layer (e.g., dielectric layer 242-1) of the plurality of second metal oxide layers on the first metal oxide layer, where the plurality of first metal oxide layers include a plurality of aluminum oxide layers, and where the plurality of second metal oxide layers include a plurality of zirconium oxide layers.

In a third implementation, alone or in combination with the first or second implementations, performing the ALD cycle further includes oxidizing the first material precursor with the alcohol oxidant to form the first metal oxide layer.

In a fourth implementation, alone or in combination with one or more of the first through third implementations, the first material precursor is trimethylaluminum (TMA) and the alcohol oxidant is tert-Butanol ((CH₃)₃COH).

In a fifth implementation, alone or in combination with one or more of the first through fourth implementations, the first metal oxide layer is formed directly on the first electrode layer.

In a sixth implementation, alone or in combination with one or more of the first through fifth implementations, the insulator layer stack includes a greater quantity of the plurality of first metal oxide layers than a quantity of the plurality of second metal oxide layers.

In a seventh implementation, alone or in combination with one or more of the first through sixth implementations, a thickness of the first metal oxide layer is greater than respective thicknesses of remaining first metal oxide layers of the plurality of first metal oxide layers.

In an eighth implementation, alone or in combination with one or more of the first through seventh implementations, a thickness of the first metal oxide layer is less than thicknesses of respective second metal oxide layers of the plurality of second metal oxide layers.

In a ninth implementation, alone or in combination with one or more of the first through eighth implementations, an additional first metal oxide layer (e.g., dielectric layer 240-3) of the plurality of first metal oxide layers is an additional outer layer of the insulator layer stack and is adjacent to the second electrode layer.

In a tenth implementation, alone or in combination with one or more of the first through eighth implementations, depositing insulator stack includes oxidizing a material precursor (e.g., an aluminum precursor such as Al(CH₃)₃) of the first metal constituent with an ozone-based oxidant to form the first metal oxide layer, where herein oxidizing the material precursor of the first metal constituent with the ozone-based oxidant results in formation of a metal oxynitride layer (e.g., a TiON interlayer 706) on the first electrode layer, and where the metal oxynitride layer contains the third metal constituent (e.g., titanium).

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

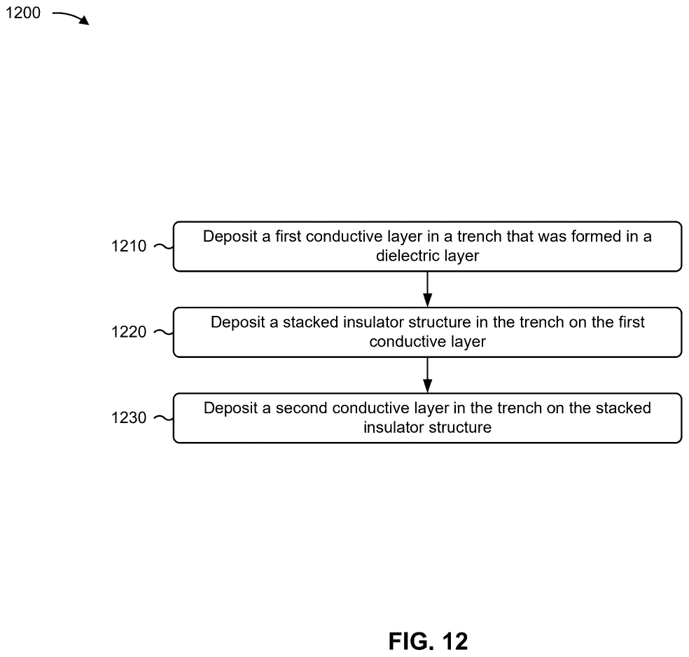

FIG. 12 is a flowchart of an example process 1200 associated with forming a semiconductor device. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include depositing a first conductive layer in a trench that was formed in a dielectric layer (block 1210). For example, one or more semiconductor processing tools may be used to deposit a first conductive layer (e.g., bottom electrode layer 236) in a trench (e.g., trench 232) that was formed in a dielectric layer (e.g., ILD layer 214 and/or ESL 216), as described herein. In some implementations, the first conductive layer extends along sidewalls and a bottom surface of the trench.

As further shown in FIG. 12, process 1200 may include depositing a stacked insulator structure in the trench on the first conductive layer (block 1220). For example, one or more semiconductor processing tools may be used to deposit a stacked insulator structure (e.g., insulator layer 238) in the trench on the first conductive layer, as described herein. In some implementations, the stacked insulator structure includes an arrangement of a plurality of nitride-free first metal oxide layers (e.g., first type dielectric layers 240) and a plurality of nitride-free second metal oxide layers (e.g., second type dielectric layers 242). In some implementations, a first nitride-free metal oxide layer (e.g., a first type dielectric layer 240-1) of the plurality of nitride-free first metal oxide layers deposited over the first conductive layer so that an interface between the first nitride-free metal oxide layer and the first conductive layer is free of nitride-containing materials. In some implementations, a second nitride-free metal oxide layer (e.g., a second type dielectric layer 242-1) is deposited over the first nitride-free metal oxide layer. In some implementations, the plurality of nitride-free first metal oxide layers contain a first metal constituent (e.g., aluminum). In some implementations, the plurality of nitride-free second metal oxide layers contain a second metal constituent (e.g., zirconium) that is different from the first metal constituent. In some implementations, the first conductive layer contains a third metal constituent (e.g., titanium) that is different from the first and second metal constituents. In some implementations, an atomic number of the first metal constituent (e.g., 13 for aluminum) is lower than an atomic number of the second metal constituent (e.g., 40 for zirconium) and an atomic number of the third metal constituent (e.g., 22 for titanium).

As further shown in FIG. 12, process 1200 may include depositing a second conductive layer in the trench on the stacked insulator structure (block 1230). For example, one or more semiconductor processing tools may be used to deposit a second conductive layer (e.g., top electrode layer 244) in the trench on the stacked insulator structure, as described herein. In some implementations, the first conductive layer, the stacked insulator structure, and the second conductive layer form a capacitor structure (e.g., trench capacitor structure 226).

Process 1200 may include additional implementations, such as any single implementation or any combination of implementations described below and/or in connection with one or more other processes described elsewhere herein.

In a first implementation, depositing the stacked insulator structure includes performing a plurality of ALD cycles to deposit a repeating layer arrangement of the plurality of nitride-free first metal oxide layers and the plurality of nitride-free second metal oxide layers, where performing the plurality of ALD cycles includes using alcohol to oxidize an aluminum-based precursor to form the plurality of nitride-free first metal oxide layers. The repeating layer arrangement may include, for example, an aluminum oxide/zirconium oxide/zirconium oxide/aluminum oxide (AZZA) repeating arrangement (where the AZZA stack repeats two or more times in the stacked insulator structure); an aluminum oxide/zirconium oxide/aluminum oxide/aluminum oxide (AZAA) repeating arrangement (where the AZAA stack repeats two or more times in the stacked insulator structure); and/or another repeating layer arrangement.

In a second implementation, alone or in combination with the first implementation, a surface of the first nitride-free metal oxide layer contacts a surface of the first conductive layer.

In a third implementation, alone or in combination with one or more of the first and second implementations, the plurality of nitride-free first metal oxide layers alternate with the plurality of nitride-free second metal oxide layers in the arrangement of the layer stack. For example, the stacked insulator structure may include an aluminum oxide/zirconium oxide/aluminum oxide/zirconium oxide/aluminum oxide (AZAZA) alternating arrangement.

In a fourth implementation, alone or in combination with one or more of the first through third implementations, ratios of a thickness of the first metal oxide layer to respective thicknesses of remaining first metal oxide layers of the stacked insulator structure are greater than approximately 1:1.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

In this way, a semiconductor device (e.g., a CMOS image sensor device, a memory device, a logic device) includes a capacitor structure (e.g., an MIM capacitor) that includes a dielectric layer stack in which the outer (e.g., upper and lower) layers are aluminum oxide (Al₂O₃) instead of another dielectric material such as zirconium oxide (ZrO₂). For example, the dielectric layer stack may include an Al₂O₃/ZrO₂/Al₂O₃/ZrO₂/Al₂O₃ (AZAZA) dielectric layer stack (or another quantity of alternating Al₂O₃/ZrO₂ layers where the outer layers are Al₂O₃) that is formed on the bottom electrode layer of the MIM capacitor without an intervening interlayer between the upper and lower aluminum oxide layers of the dielectric layer stack and the electrode layers of the MIM capacitor.

The arrangement of the aluminum oxide layers at a bottom and at a top of the dielectric layer stack prevents oxygen migration from the zirconium oxide layers to the electrode layers of the MIM capacitor, while achieving higher capacitance levels than those of MIM capacitors incorporating other types of dielectric materials in the outer layers in a dielectric stack of an insulator layer such as a ZrO₂/Al₂O₃/ZrO₂ (ZAZ) dielectric layer stack and an interlayer. In particular, the outer aluminum oxide layers of the dielectric layer stack are more resistant to oxygen migration than the zirconium oxide layers of the dielectric layer stack, and therefore exhibit less oxygen loss to the electrode layers of the MIM capacitor (and, accordingly, fewer oxygen vacancies). The fewer oxygen vacancies in the outer aluminum oxide layers results in the outer aluminum oxide layers being less susceptible to charge trapping, thereby enabling faster discharge times to be achieved for the MIM capacitor. The faster discharge times for the MIM capacitor may enable images and/or video to be generated with reduced lag in use cases in which the MIM capacitor is included in image sensor device for charge overflow storage. Additionally and/or alternatively, the faster discharge times for the MIM capacitor may enable faster read times and/or faster erase times to be achieved for a memory cell (e.g., a DRAM cell) in which the MIM capacitor is included in a memory device. Additionally and/or alternatively, the faster discharge times for the MIM capacitor may enable increased charge smoothing performance where the MIM capacitor is included in a power supply.

As described in greater detail above, some implementations described herein provide a method. The method includes etching a trench in a dielectric layer. The method includes depositing, in the trench, a first electrode layer of a semiconductor structure. The method includes depositing, in the trench, an insulator layer stack of the semiconductor structure on the first electrode layer. The method includes depositing, in the trench, a second electrode layer of the semiconductor structure on the insulator layer stack. The insulator layer stack includes a first metal oxide layer containing a first metal constituent, and a second metal oxide layer containing a second metal constituent that is different from the first metal constituent. The first metal oxide layer has a dielectric constant that is lower than a dielectric constant of the second metal oxide layer. The first metal constituent and the second metal constituent are different from a third metal constituent of the first electrode layer. The first metal oxide layer is closer to the first electrode layer than the second metal oxide layer. An interface between the first metal oxide layer and the first electrode layer is free of the second metal constituent.

As described in greater detail above, some implementations described herein provide a method. The method includes etching a trench in a dielectric layer. The method includes depositing, in the trench, a first electrode layer of a capacitor structure. The method includes depositing, in the trench, an insulator layer stack of the capacitor structure on the first electrode layer. The method includes depositing, in the trench, a second electrode layer of the capacitor structure on the insulator layer stack, where the insulator layer stack includes a plurality of first metal oxide layers and a plurality of second metal oxide layers, and where a first metal oxide layer of the plurality of first metal oxide layers is an outer layer of the insulator layer stack and is adjacent to the first electrode layer.

As described in greater detail above, some implementations described herein provide a method. The method includes depositing a first conductive layer in a trench that was formed in a dielectric layer, where the first conductive layer extends along sidewalls and a bottom surface of the trench. The method includes depositing a stacked insulator structure in the trench on the first conductive layer, where the stacked insulator structure includes layers of a first metal oxide and a second metal oxide, where a first layer of the stacked insulator structure deposited on the first conductive layer is a first metal oxide layer. The method includes depositing a second conductive layer in the trench on the stacked insulator structure.

As described in greater detail above, some implementations described herein provide a method. The method includes depositing a first conductive layer in a trench that was formed in a dielectric layer, where the first conductive layer extends along sidewalls and a bottom surface of the trench. The method includes depositing a stacked insulator structure in the trench on the first conductive layer. The method includes depositing a second conductive layer in the trench on the stacked insulator structure. The stacked insulator structure includes an arrangement of a plurality of nitride-free first metal oxide layers and a plurality of nitride-free second metal oxide layers. A first nitride-free metal oxide layer of the plurality of nitride-free first metal oxide layers deposited over the first conductive layer so that an interface between the first nitride-free metal oxide layer and the first conductive layer is free of nitride-containing materials. A second nitride-free metal oxide layer is deposited over the first nitride-free metal oxide layer. The plurality of nitride-free first metal oxide layers contain a first metal constituent. The plurality of nitride-free second metal oxide layers contain a second metal constituent that is different from the first metal constituent. The first conductive layer contains a third metal constituent that is different from the first and second metal constituents. An atomic number of the first metal constituent is lower than an atomic number of the second metal constituent and an atomic number of the third metal constituent.

As described in greater detail above, some implementations described herein provide a capacitor structure. The capacitor structure includes a first electrode layer that extends along sidewalls and a bottom surface of a trench. The capacitor structure includes a second electrode layer that extends in the trench. The capacitor structure includes an insulator structure between the first electrode layer and the second electrode layer, where the insulator structure extends along the sidewalls and the bottom surface of the trench, where the insulator structure includes a plurality of first metal oxide layers and a plurality of second metal oxide layers, where respective first metal oxide layers of the plurality of first metal oxide layers are stacked with respective second metal oxide layers of the plurality of second metal oxide layers, and where a first metal oxide layer of the plurality of first metal oxide layers abuts the first electrode layer.

As described in greater detail above, some implementations described herein provide a semiconductor structure. The semiconductor structure includes a first electrode layer that extends along sidewalls and a bottom surface of a trench. The semiconductor structure includes a second electrode layer that extends in the trench, where between the first electrode layer and the second electrode layer is free of an oxynitride of a metal of the first electrode layer and the second electrode layer. The semiconductor structure includes an insulator structure between the first electrode layer and the second electrode layer. The insulator structure extends along the sidewalls and the bottom surface of the trench. The insulator structure comprises an arrangement of a plurality of first metal oxide layers and a plurality of second metal oxide layers. The arrangement is oriented in a direction approximately perpendicular to the first electrode layer and the second electrode layer. A first metal oxide layer of the plurality of first metal oxide layers abuts the first electrode layer. The plurality of first metal oxide layers have a dielectric constant that is lower than a dielectric constant of the plurality of second metal oxide layers.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
etching a trench in a dielectric layer;
depositing, in the trench, a first electrode layer of a semiconductor structure;
depositing, in the trench, an insulator layer stack of the semiconductor structure on the first electrode layer; and
depositing, in the trench, a second electrode layer of the semiconductor structure on the insulator layer stack,
wherein the insulator layer stack comprises:
a first metal oxide layer containing a first metal constituent, and
a second metal oxide layer containing a second metal constituent that is different from the first metal constituent,
wherein the first metal oxide layer has a dielectric constant that is lower than a dielectric constant of the second metal oxide layer,
wherein the first metal constituent and the second metal constituent are different from a third metal constituent of the first electrode layer,
wherein the first metal oxide layer is closer to the first electrode layer than the second metal oxide layer, and
wherein an interface between the first metal oxide layer and the first electrode layer is free of the second metal constituent.

2. The method of claim 1, wherein depositing the insulator layer stack comprises:
performing a plurality of atomic layer deposition (ALD) cycles to deposit the insulator layer stack,
wherein performing an ALD cycle, of the plurality of ALD cycles, comprises:
depositing, using a first material precursor and an alcohol oxidant, the first metal oxide layer on the first electrode layer; and
depositing, using a second material precursor, the second metal oxide layer on the first metal oxide layer,
wherein the first material precursor is an aluminum precursor, and
wherein the second material precursor is a zirconium precursor.

3. The method of claim 2, wherein performing the ALD cycle further comprises:
oxidizing the first material precursor with the alcohol oxidant to form the first metal oxide layer.

4. The method of claim 3, wherein the first material precursor is trimethylaluminum (TMA) and the alcohol oxidant is tert-Butanol ((CH₃)₃COH).

5. The method of claim 1, wherein the first metal oxide layer is formed directly on the first electrode layer.

6. The method of claim 1, wherein the insulator layer stack comprises:
a plurality of the first metal oxide layers; and
a plurality of second metal oxide layers,
wherein a quantity of the plurality of first metal oxide layers is greater than a quantity of the plurality of second metal oxide layers.

7. The method of claim 6, wherein a thickness of the first metal oxide layer is greater than respective thicknesses of remaining first metal oxide layers of the plurality of first metal oxide layers.

8. The method of claim 6, wherein a thickness of the first metal oxide layer is less than thicknesses of respective second metal oxide layers of the plurality of second metal oxide layers.

9. The method of claim 1, wherein depositing insulator stack comprises:
oxidizing a material precursor of the first metal constituent with an ozone-based oxidant to form the first metal oxide layer,
wherein oxidizing the material precursor of the first metal constituent with the ozone-based oxidant results in formation of a metal oxynitride layer on the first electrode layer, and
wherein the metal oxynitride layer contains the third metal constituent.

10. A method, comprising:
depositing a first conductive layer in a trench that was formed in a dielectric layer,
wherein the first conductive layer extends along sidewalls and a bottom surface of the trench;
depositing a stacked insulator structure in the trench on the first conductive layer,
wherein the stacked insulator structure comprises an arrangement of a plurality of nitride-free first metal oxide layers and a plurality of nitride-free second metal oxide layers,
wherein a first nitride-free metal oxide layer of the plurality of nitride-free first metal oxide layers deposited over the first conductive layer so that an interface between the first nitride-free metal oxide layer and the first conductive layer is free of nitride-containing materials,
wherein a second nitride-free metal oxide layer is deposited over the first nitride-free metal oxide layer,
wherein the plurality of nitride-free first metal oxide layers contain a first metal constituent,
wherein the plurality of nitride-free second metal oxide layers contain a second metal constituent that is different from the first metal constituent,
wherein the first conductive layer contains a third metal constituent that is different from the first and second metal constituents, and
wherein an atomic number of the first metal constituent is lower than an atomic number of the second metal constituent and an atomic number of the third metal constituent; and
depositing a second conductive layer in the trench on the stacked insulator structure.

11. The method of claim 10, wherein depositing the stacked insulator structure comprises:
performing a plurality of atomic layer deposition (ALD) cycles to deposit a repeating layer arrangement of the plurality of nitride-free first metal oxide layers and the plurality of nitride-free second metal oxide layers,
wherein performing the plurality of ALD cycles comprises using alcohol to oxidize an aluminum-based precursor to form the plurality of nitride-free first metal oxide layers.

12. The method of claim 10, wherein a surface of the first nitride-free metal oxide layer contacts a surface of the first conductive layer.

13. The method of claim 10, wherein the plurality of nitride-free first metal oxide layers alternate with the plurality of nitride-free second metal oxide layers in the arrangement of the stacked insulator structure.

14. The method of claim 10, wherein ratios of a thickness of the first nitride-free metal oxide layer to respective thicknesses of remaining ones of the plurality of nitride-free first metal oxide layers of the stacked insulator structure are greater than approximately 1:1.

15. A semiconductor structure, comprising:
a first electrode layer that extends along sidewalls and a bottom surface of a trench;
a second electrode layer that extends in the trench,
wherein between the first electrode layer and the second electrode layer is free of an oxynitride of a metal of the first electrode layer and the second electrode layer; and
an insulator structure between the first electrode layer and the second electrode layer,
wherein the insulator structure extends along the sidewalls and the bottom surface of the trench,
wherein the insulator structure comprises an arrangement of a plurality of first metal oxide layers and a plurality of second metal oxide layers,
wherein the arrangement is oriented in a direction approximately perpendicular to the first electrode layer and the second electrode layer,
wherein a first metal oxide layer of the plurality of first metal oxide layers abuts the first electrode layer, and
wherein the plurality of first metal oxide layers have a dielectric constant that is lower than a dielectric constant of the plurality of second metal oxide layers.

16. The capacitor structure of claim 15, wherein the plurality of first metal oxide layers are aluminum oxide layers, and
wherein the plurality of second metal oxide layers are zirconium oxide layers.

17. The capacitor structure of claim 15, wherein an additional first metal oxide layer of the plurality of first metal oxide layers abuts the second electrode layer, and
wherein a thickness of the first metal oxide layer is greater than a thickness of the additional first metal oxide layer.

18. The capacitor structure of claim 17, wherein a plurality of surfaces of the second electrode layer are directly on a plurality of surfaces of the additional first metal oxide layer.

19. The capacitor structure of claim 15, wherein a thickness of the first metal oxide layer is greater than respective thicknesses of remaining first metal oxide layers of the plurality of first metal oxide layers.

20. The capacitor structure of claim 15, wherein a plurality of surfaces of the first metal oxide layer are directly on a plurality of surfaces of the first electrode layer.
